(19) United States
(12) Patent Application Publication
(10) Pub. No.: US 2026/0150163 A1
(43) Pub. Date: May 28, 2026

(54) LIGHT EMITTING APPARATUS

(71) Applicant: SEOUL SEMICONDUCTOR CO., LTD., Ansan-si (KR)

(72) Inventors: ChungHoon LEE, Ansan-si (KR); KeonYoung LEE, Ansan-si (KR)

(73) Assignee: SEOUL SEMICONDUCTOR CO., LTD., Ansan-si (KR)

(21) Appl. No.: 19/377,904

(22) Filed: Nov. 3, 2025

Related U.S. Application Data
(60) Provisional application No. 63/717,937, filed on Nov. 8, 2024.
(60) Provisional application No. 63/739,188, filed on Dec. 27, 2024.
(60) Provisional application No. 63/741,247, filed on Jan. 2, 2025.

(51) Int. Cl. H05B 45/20; F21K 9/232; F21K 9/238; F21Y 113/13; F21Y 115/10; G02F 1/13357; H05B 45/10; H05B 45/325; H05B 45/33; H10H 20/811; H10H 29/14; H10H 29/24; H10H 29/80

(52) U.S. Cl. CPC H05B 45/20; H05B 45/10; H05B 45/325; H05B 45/33; H10H 20/811; H10H 29/24; F21K 9/232; F21K 9/238; F21Y 2113/13; F21Y 2115/10; G02F 1/133603; G02F 1/133609; H10H 29/14; H10H 29/962

(57) ABSTRACT

A light emitting apparatus includes: a substrate; a first light emitting device disposed on the substrate and configured to generate light of a first emission spectrum having a first dominant wavelength by a current supplied through the substrate; and a second light emitting device disposed on the substrate and configured to generate light of a second emission spectrum having a second dominant wavelength and at least partially overlapping with the first emission spectrum. An intensity of the first dominant wavelength and an intensity of the second dominant wavelength are different from each other.

### CROSS-REFERENCE TO RELATED APPLICATIONS

The present application claims the benefit of priority to U.S. provisional Application Nos. 63/717,937, filed Nov. 8, 2024; 63/739,188, filed Dec. 27, 2024; and 63/741,247, filed Jan. 2, 2025, the contents of each of which is incorporated herein by reference.

### TECHNICAL FIELD

Various implementations of the disclosed technology relate to a light emitting apparatus.

### BACKGROUND

Recently, Light Emitting Diodes (LEDs) have been widely used. A light emitting diode converts an electrical signal into a form of light, such as infrared, visible, or ultraviolet light, using characteristics of a compound semiconductor.

As the luminous efficiency of light emitting diodes is increased, light emitting devices are being applied to various fields including display devices, lighting equipment, and vehicles.

### SUMMARY

Exemplary embodiments of the disclosed technology may provide a light emitting apparatus with an improved Color Rendering Index (CRI).

Furthermore, embodiments of the disclosed technology may provide a light emitting apparatus in which color rendering is improved and costs may be reduced.

Furthermore, embodiments of the disclosed technology may provide a light emitting apparatus that may have a wide color gamut and an increased color reproduction rate.

Furthermore, embodiments of the disclosed technology may provide a light emitting apparatus that may have improved reliability.

Furthermore, embodiments of the disclosed technology may provide a light emitting apparatus with increased light extraction efficiency.

Furthermore, embodiments of the disclosed technology may solve a problem in which a difference occurs between a pre-designed change ratio for each wavelength and an actual ratio due to deterioration, thereby providing a light emitting apparatus that is stable against temperature changes.

Furthermore, embodiments of the disclosed technology may provide a light emitting apparatus with reduced production costs by reducing the content of (or not using) a phosphor. Furthermore, embodiments of the disclosed technology may provide a light emitting apparatus that may be implemented in a small size.

In accordance with one aspect of the disclosed technology, there is provided a light emitting apparatus including: a substrate; a first light emitting device disposed on the substrate and configured to generate light of a first emission spectrum having a first dominant wavelength by a current supplied through the substrate; and a second light emitting device disposed on the substrate and configured to generate light of a second emission spectrum having a second dominant wavelength and at least partially overlapping with the first emission spectrum, wherein an intensity of the first dominant wavelength and an intensity of the second dominant wavelength are different from each other.

Further, the intensity of the first dominant wavelength may change in response to a current density supplied to the first light emitting device, and the intensity of the second dominant wavelength may change in response to a current density supplied to the second light emitting device.

Further, when the current density supplied to the first light emitting device increases, a wavelength of the first dominant wavelength may decrease, and the intensity of the first dominant wavelength may increase, and when the current density supplied to the first light emitting device decreases, the wavelength of the first dominant wavelength may increase, and the intensity of the first dominant wavelength may decrease, and when the current density supplied to the second light emitting device increases, a wavelength of the second dominant wavelength may decrease, and the intensity of the second dominant wavelength may increase, and when the current density supplied to the second light emitting device decreases, the wavelength of the second dominant wavelength may increase, and the intensity of the second dominant wavelength may decrease.

Further, the light emitting apparatus may further include: a controller configured to control a current density supplied to the first light emitting device and a current density supplied to the second light emitting device to control the first dominant wavelength and the second dominant wavelength.

Further, the controller may be configured to control the current density supplied to the first light emitting device to be smaller than the current density supplied to the second light emitting device.

Further, the controller may control the current such that the current is supplied to the first light emitting device and the second light emitting device for a predetermined current supply time, and a first current supply time during which the current is supplied to the first light emitting device may be greater than a second current supply time during which the current is supplied to the second light emitting device.

Further, the first current supply time during which current is supplied to the first light emitting device may be shorter than the second current supply time during which current is supplied to the second light emitting device.

Further, the controller may be configured to control the current such that a period in which no current is supplied to the first light emitting device and the second light emitting device is formed between the first current supply time during which the current is supplied to the first light emitting device and the second current supply time during which the current is supplied to the second light emitting device.

Further, a time of the period in which no current is supplied may be shorter than the first current supply time during which the current is supplied to the first light emitting device.

Further, a time of the period in which no current is supplied may be longer than the first current supply time during which the current is supplied to the first light emitting device.

Further, the light emitting apparatus may further include: a third light emitting device disposed on the substrate and configured to generate light of a third emission spectrum having a third dominant wavelength and at least partially overlapping with the second emission spectrum by the current supplied through the substrate, and the controller may be further configured to control a current density supplied to the third light emitting device to control the third dominant wavelength, and control the current density supplied to the third light emitting device to be greater than the current density supplied to the second light emitting device.

Further, the controller may supply a current waveform to at least one of the plurality of light emitting devices, the current waveform may have a first current density in a first time period and a second current density in a second time period, and the first charge density per unit area may be defined by Equation 1:

$$C 1 = {J}_{1} \times T {a}_{1} \qquad ( Equation 1 )$$

where C1 is the first charge density per unit area,
   J1 is the first current density, and
   Ta1 is the first time period

Further, a second charge density per unit area may be defined by Equation 2:

$$C 2 = {J}_{2} \times {Tb}_{1} \qquad ( Equation 2 )$$

where C2 is the second charge density per unit area
   J2 is the second current density
   Tb1 is the second time period

Further, the first charge density per unit area C1 and the second charge density per unit area C2 may be represented by Equation 3:

$$90 \% \leq C 1 \div C 2 \leq 110 \% \qquad ( Equation 3 )$$

Further, each of the current supply times may be shorter than each of the current supply times.

Further, the current supply time may be represented by Equation 4:

$$0.9 \leq \frac{{J}_{1} \times {Ta}_{2 n + 1}}{{J}_{2} \times {Tb}_{2 n + 1}} \leq 1.1 \qquad ( Equation 4 )$$

Further, the first light emitting device and the second light emitting device may generate light such that an overlapped spectrum is formed in which the first emission spectrum and the second emission spectrum at least partially overlap each other, and a plurality of peaks may be formed in the overlapped spectrum.

Further, the overlapped spectrum may have a color temperature corresponding to white light.

Further, each of the first light emitting device and the second light emitting device may include: a first conductivity-type semiconductor layer; an active region stacked on the first conductivity-type semiconductor layer; and a second conductivity-type semiconductor layer stacked on the active region.

Further, each of the first light emitting device and the second light emitting device may include: a first conductivity-type semiconductor layer; a superlattice layer stacked above the first conductivity-type semiconductor layer; and a second conductivity-type semiconductor layer stacked above the superlattice layer, and the superlattice layer may include Indium Gallium Nitride (InGaN).

Further, a plurality of the superlattice layers may be formed, and the plurality of superlattice layers may include: a first superlattice layer stacked on the first conductivity-type semiconductor layer; and a second superlattice layer stacked above the first superlattice layer, and a content of indium included in the first superlattice layer and a content of indium included in the second superlattice layer may be different from each other.

In accordance with one aspect of the disclosed technology, there is provided a light emitting apparatus including: a substrate; a first light emitting device disposed on the substrate and configured to generate light of a first emission spectrum having a first dominant wavelength; and a second light emitting device disposed on the substrate and configured to generate light of a second emission spectrum having a second dominant wavelength and at least partially overlapping with the first emission spectrum, wherein each of the first light emitting device and the second light emitting device includes: a first conductivity-type semiconductor layer; an active region stacked above the first conductivity-type semiconductor layer; a second conductivity-type semiconductor layer stacked above the active region; a first electrode electrically connected to the second conductivity-type semiconductor layer; and a second electrode electrically connected to the first conductivity-type semiconductor layer, and the second electrode of the first light emitting device and the second electrode of the second light emitting device are integrally formed.

In accordance with one aspect of the disclosed technology, there is provided a light emitting apparatus including: a substrate; a first active region disposed on the substrate and configured to generate light of a first emission spectrum having a first dominant wavelength by a current supplied through the substrate; and a second active region disposed on the substrate and configured to generate light of a second emission spectrum having a second dominant wavelength and at least partially overlapping with the first emission spectrum, wherein an intensity at the first dominant wavelength and an intensity at the second dominant wavelength are different from each other.

Further, the intensity at the first dominant wavelength may change in response to a current density supplied to the first active region, and the intensity at the second dominant wavelength may change in response to a current density supplied to the second active region.

Further, the light emitting apparatus may further include: a controller configured to control the current density supplied to the first active region and a current density supplied to the second active region to control the first dominant wavelength and the second dominant wavelength.

Embodiments of the disclosed technology may improve the Color Rendering Index (CRI).

Furthermore, compared to the prior art, embodiments of the disclosed technology may improve color rendering while reducing an increase in cost.

Furthermore, embodiments of the disclosed technology may achieve a wide color gamut and increase a color reproduction rate.

Furthermore, embodiments of the disclosed technology may improve reliability.

Furthermore, embodiments of the disclosed technology may increase light extraction efficiency.

Furthermore, embodiments of the disclosed technology may solve a problem in which a difference occurs between a pre-designed ratio of blue light, red light, and green light and an actual ratio due to deterioration, thereby providing a light emitting apparatus that is stable against temperature changes.

Furthermore, embodiments of the disclosed technology may reduce production costs by reducing the content of or not using a phosphor.

Furthermore, embodiments of the disclosed technology may be implemented in a small size.

### BRIEF DESCRIPTION OF THE DRAWINGS

FIG. 1 is a diagram showing a lighting apparatus including a light emitting apparatus according to a first embodiment of the disclosed technology.

FIG. 2 is a diagram showing a display apparatus including a light emitting apparatus according to a first embodiment of the disclosed technology.

FIG. 3 is a diagram showing a state where a first active region and a second active region are included in a light emitting device of the light emitting apparatus according to the first embodiment of the disclosed technology.

FIG. 4 is a diagram showing a state where a third active region is further included in the light emitting device of FIG. 3.

FIG. 5 is a graph showing a change in a spectrum according to a current supplied to the light emitting device of the light emitting apparatus of FIG. 3.

FIG. 6 is an enlarged graph of the spectrum according to the current of FIG. 5.

FIG. 7 is a diagram showing a light emitting device disposed on a substrate according to a second embodiment of the disclosed technology.

FIG. 8 is a cross-sectional view of the light emitting device of FIG. 7, taken along the line A-A′.

FIG. 9 is a diagram showing a light emitting device disposed on a substrate according to a third embodiment of the disclosed technology.

FIG. 10 is a diagram showing a plurality of emission spectra of the light emitting apparatus of FIG. 9.

FIG. 11 is a diagram showing that the plurality of emission spectra of FIG. 10 are changed according to current density.

FIG. 12 is a diagram showing an overlapped spectrum in which the plurality of emission spectra of FIG. 10 are overlapped.

FIG. 13 is a diagram showing a plurality of light emitting devices disposed on a substrate according to a fourth embodiment of the disclosed technology.

FIG. 14 is a diagram showing a first current waveform supplied to the light emitting apparatus of the disclosed technology.

FIG. 15 is a diagram showing a second current waveform supplied to the light emitting apparatus of the disclosed technology.

FIG. 16 is a diagram showing a third current waveform supplied to the light emitting apparatus of the disclosed technology.

FIG. 17 is a diagram showing a fourth current waveform and a fifth current waveform supplied to the light emitting apparatus of the disclosed technology.

FIG. 18 is a diagram showing a first current waveform and a second current waveform supplied to the light emitting apparatus of the disclosed technology.

FIG. 19 is a diagram showing a sixth current waveform supplied to the light emitting apparatus of the disclosed technology.

FIG. 20 is a diagram showing a seventh current waveform supplied to the light emitting apparatus of the disclosed technology.

FIG. 21 is a diagram showing an eighth current waveform supplied to the light emitting apparatus of the disclosed technology.

FIG. 22 is a diagram showing a ninth current waveform supplied to the light emitting apparatus of the disclosed technology.

FIG. 23 is a diagram showing a light emitting device disposed on a substrate according to a fifth embodiment of the disclosed technology.

FIG. 24 is a diagram showing a light emitting device disposed on a substrate according to a sixth embodiment of the disclosed technology.

FIG. 25 is a diagram showing a light emitting device disposed on a substrate according to a seventh embodiment of the disclosed technology.

FIG. 26 is a diagram showing a light emitting device disposed on a substrate according to an eighth embodiment of the disclosed technology.

FIG. 27 is a graph showing a rate of change of a dominant wavelength for each current density supplied to the light emitting device of the disclosed technology.

FIG. 28 is a diagram showing a light emitting apparatus according to an eighth embodiment of the disclosed technology.

FIG. 29 is a diagram showing an overlapped spectrum in which a plurality of emission spectra are overlapped.

### DETAILED DESCRIPTION

In the following description, for the purposes of explanation, numerous specific details are set forth in order to provide a thorough understanding of various exemplary embodiments or implementations of the present disclosure. As used herein, “embodiments” and “implementations” are interchangeable terms for words that are non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”)), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property, etc., of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite to the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1D1-axis, the DR2D2-axis, and the DR3D3-axis are not limited to three axes of a rectangular coordinate system, such as the x, y, and z-axes, and may be interpreted in a broader sense. For example, the DR1D1-axis, the DR2D2-axis, and the DR3D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting apparatus 1 according to a first embodiment of the disclosed technology will be described.

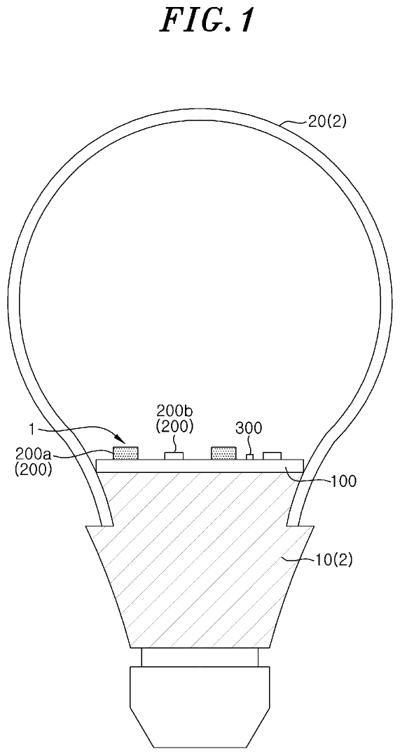

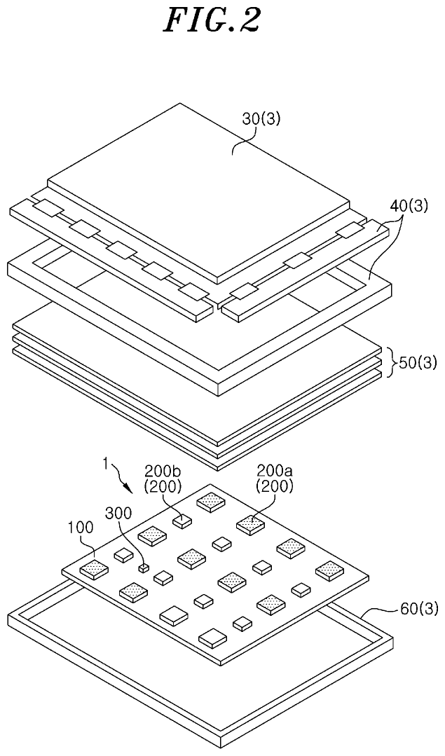

Referring to FIGS. 1 and 2, a light emitting apparatus 1 according to a first embodiment the disclosed technology may generate light. The light emitting apparatus 1 may be included in a window, a windshield, a rear window, a tail light, a headlight, a rear lamp, a tail lamp, an interior light, a brake light, etc. of a vehicle.

In one example, the light emitting apparatus 1 may be included in a lighting apparatus 2. The lighting apparatus 2 may include a lighting body 10 and a lighting cover 20. The light emitting apparatus 1 may be disposed in the lighting body 10. Various components such as elements, wiring, etc. for an operation of the light emitting apparatus 1 may be disposed inside the lighting body 10. Furthermore, the lighting body 10 may include a heat sink and a socket connected to an external power source. Light may be transmitted through the lighting cover 20. The lighting cover 20 may be coupled to the lighting body 10 to cover the light emitting apparatus 1.

In another example, the light emitting apparatus 1 may be included in a display apparatus 3. The display apparatus 3 may be a display device. The display apparatus 3 may include a display panel 30, a driving substrate 40, an optical sheet 50, and a lower cover 60. The display panel 30 may include a thin film transistor substrate and a color filter substrate that are bonded to face each other such that a uniform cell gap is maintained. Furthermore, the display panel 30 may include a liquid crystal layer disposed between the thin film transistor substrate and the color filter substrate. A driving substrate configured to supply a driving signal to a gate line and a data line may be disposed at an edge of the display panel 30.

The driving substrate 40 may be electrically connected to the display panel 30 by a Chip On Film (COF). The COF may be changed to a Tape Carrier Package (TCP). The optical sheet 50 may include a diffusion sheet, a condensing sheet, and a protective sheet. The optical sheet 50 may include one diffusion sheet and two condensing sheets, or may include two diffusion sheets and one condensing sheet. The lower cover 60 may have a structure with an open upper surface and may accommodate the optical sheet 50 and the light emitting apparatus 1. In other words, the light emitting apparatus 1 may be disposed between the optical sheet 50 and the lower cover 60. Furthermore, the display apparatus 3 may further include a reflective sheet disposed on an upper surface or a lower surface of the light emitting apparatus 1. The reflective sheet may reflect light toward the optical sheet 50.

The light emitting apparatus 1 may include a substrate 100, a light emitting device 200, and a controller 300.

The light emitting device 200 and the controller 300 may be disposed on the substrate 100. For example, the substrate 100 may be a printed circuit board (PCB) on which an electric circuit is formed. Furthermore, the substrate 100 may include an alloy including at least one of Cu, Zn, Au, Ni, Al, Mg, Cd, Be, W, Mo, Si, Ag, and Fe, or some of these. However, this is merely an example, and the substrate 100 may include at least one of FR1, CEM-1, and FR-4. Here, FR1 is a material in which copper foil and laminate paper are stacked, and CEM-1 is a material in which copper foil, glass fiber fabric, laminate paper, and glass fiber fabric are sequentially stacked. Furthermore, FR-4 is a material in which copper foil and glass fiber fabric or glass fiber fabric are stacked. In addition, the substrate 100 may include a ceramic such as alumina (Al2O3), aluminum nitride (AlN), or Zirconia Toughened Alumina (ZTA), etc. Furthermore, the substrate 100 may include a printed circuit board and a growth substrate for growing the light emitting device 200.

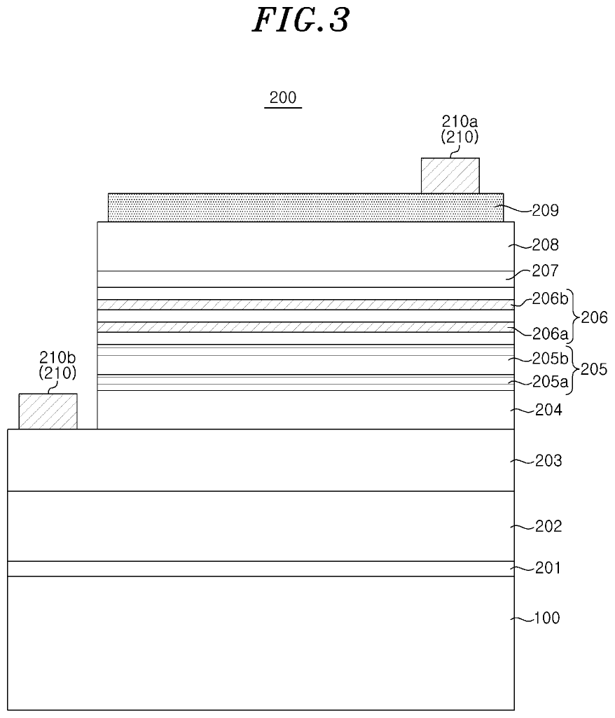

Further referring to FIG. 3, the light emitting device 200 may generate light. For example, the light emitting device 200 may be an element that converts electrical energy into light, such as a Light Emitting Diode, a laser diode, or an organic light-emitting diode. The light emitting device 200 may generate at least one of UVC (200 nm to 280 nm), UVB (280 nm to 315 nm), UVA (315 nm to 420 nm), blue light, green light, yellow light, red light, infrared light, and white light. The light emitting device 200 may be electrically connected to the substrate 100 and receive power from an external source to generate light. Furthermore, a plurality of light emitting devices 200 may be formed. The plurality of light emitting devices 200 may include a first light emitting device 200a and a second light emitting device 200b. The first light emitting device 200a and the second light emitting device 200b may generate light with different peak wavelengths.

Each of the plurality of light emitting devices 200 may include a buffer layer 201, an undoped layer 202, a first conductivity-type semiconductor layer 203, a strain control layer 204, a superlattice layer 205, an active region 206, an electron blocking layer 207, a second conductivity-type semiconductor layer 208, a transparent electrode layer 209, and an electrode 210.

The buffer layer 201 may be a layer disposed on the substrate 100 for growing a gallium nitride-based semiconductor layer. For example, the buffer layer 201 may include AlGaN. The buffer layer 201 may adjust a difference in thermal expansion coefficients between the gallium nitride-based semiconductor layer and the substrate 100 to alleviate thermal stress. The buffer layer 201 may prevent defects or non-uniformity of the substrate 100 from propagating to the gallium nitride-based semiconductor layer. In addition, the buffer layer 201 may buffer a difference in lattice constants between the substrate 100 and the gallium nitride-based semiconductor layer to reduce an occurrence of defects.

The undoped layer 202 may be stacked on the buffer layer 201. The undoped layer 202 may control a current flow of the substrate 100 or form an electrical barrier. In other words, the undoped layer 202 may act as an insulating layer.

The first conductivity-type semiconductor layer 203 may include n-type impurities (e.g., Si, Ge, Sn). The first conductivity-type semiconductor layer 203 may be an n-type semiconductor layer. However, this is merely an example, and the first conductivity-type semiconductor layer 203 may also include p-type impurities. Furthermore, the first conductivity-type semiconductor layer 203 may be electrically connected to the substrate 100 through the electrode 210.

The strain control layer 204 may be stacked on the first conductivity-type semiconductor layer 203. The strain control layer 204 may be disposed between the first conductivity-type semiconductor layer 203 and the superlattice layer 205 to reduce a difference in lattice constants between the first conductivity-type semiconductor layer 203 and the superlattice layer 205. The strain control layer 204 may prevent defects from occurring in the first conductivity-type semiconductor layer 203 and the superlattice layer 205 and enhance a bonding force between the first conductivity-type semiconductor layer 203 and the superlattice layer 205. The strain control layer 204 may alleviate thermal stress caused by a difference in thermal expansion coefficients between the first conductivity-type semiconductor layer 203 and the superlattice layer 205 to increase stability and reliability. The strain control layer 204 may improve an electrical junction between the first conductivity-type semiconductor layer 203 and the superlattice layer 205 to optimize a current flow and charge mobility.

The superlattice layer 205 is stacked on the strain control layer 204 and may generate light. The superlattice layer 205 may include a plurality of material layers including different materials. A plurality of material layers may be alternately stacked. The materials may include GaAs, AlGaAs, InGaN, GaN, InGaAs, InP, etc. Hereinafter, the superlattice layer 205 will be described as including alternately stacked InGaN layers and GaN layers, but is not limited thereto. The superlattice layer 205 may include at least one of a first superlattice layer 205a and a second superlattice layer 205b.

The first superlattice layer 205a may be stacked on the strain control layer 204. The first superlattice layer 205a may include InGaN layers and GaN layers alternately stacked in 3 to 4 periods. A thickness of an InGaN layer of the first superlattice layer 205a and a thickness of a GaN layer of the first superlattice layer 205a may be formed to be different from each other. For example, a thickness of an InGaN layer of the first superlattice layer 205a may be smaller than a thickness of a GaN layer of the first superlattice layer 205a.

The second superlattice layer 205b may be stacked on the first superlattice layer 205a. The second superlattice layer 205b may include InGaN layers and GaN layers alternately stacked in more periods than the first superlattice layer 205a. For example, the second superlattice layer 205b may include InGaN layers and GaN layers alternately stacked in 5 to 6 periods. A content of In in an InGaN layer of the second superlattice layer 205b and a content of In in an InGaN layer of the first superlattice layer 205a may be different from each other. For example, a content of In in an InGaN layer of the second superlattice layer 205b may be formed to be greater than a content of In in an InGaN layer of the first superlattice layer 205a. The first superlattice layer 205a and the second superlattice layer 205b may have different bandgap energies. In other words, the first superlattice layer 205a and the second superlattice layer 205b may generate light having different peak wavelengths.

The active region 206 may be stacked on the superlattice layer 205. The active region 206 may generate light. The active region 206 may include a well layer and a barrier layer. The active region 206 may have a single quantum well structure including a single well layer or a multiple quantum well structure including a plurality of well layers. For example, a number of well layers may be 1 to 10. The well layer may include InGaN. The well layer may include a higher content of In than a barrier layer to generate long-wavelength light. A composition ratio of In in the well layer may be 0.15 or more and 0.2 or less with respect to a total composition of the well layer. The barrier layer may include a GaN layer. Furthermore, the active region 206 may include at least one of a first active region 206a and a second active region 206b. The first active region 206a and the second active region 206b may generate light with different peak wavelengths.

The first active region 206a may generate light with a peak wavelength between 440 nm and 470 nm. In other words, the first active region 206a may generate blue light. The first active region 206a may include 5 to 7 well layers.

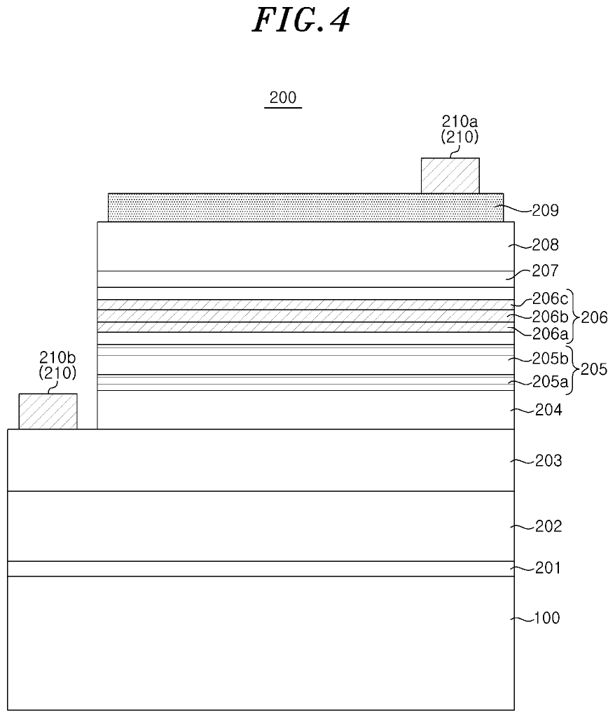

The second active region 206b may generate light having a different peak wavelength from light generated from the first active region 206a and light generated from a third active region 206c. See FIG. 4. For example, the second active region 206b may generate light with a peak wavelength between 500 nm and 600 nm. In other words, the second active region 206b may generate green light. The second active region 206b may include 5 to 7 well layers.

Further referring to FIG. 4, the active region 206 may further include the third active region 206c. The third active region 206c may generate light having a different peak wavelength from light generated from the second active region 206b and light generated from the first active region 206a. For example, the third active region 206c may generate light with a peak wavelength between 600 nm and 670 nm. In other words, the third active region 206c may generate red light. The third active region 206c may include 5 to 10 well layers.

The electron blocking layer 207 may be stacked on the active region 206. The electron blocking layer 207 may be formed along a surface of the active region 206. The electron blocking layer 207 may be disposed between the active region 206 and the second conductivity-type semiconductor layer 208 to prevent electrons from escaping to the second conductivity-type semiconductor layer 208. In other words, the electron blocking layer 207 may confine electrons in the active region 206 to reduce optical crosstalk and improve luminous efficiency.

The second conductivity-type semiconductor layer 208 may include p-type impurities (e.g., Mg, Sr, or Ba). In other words, the second conductivity-type semiconductor layer 208 may be a p-type semiconductor layer. However, this is merely an example, and the second conductivity-type semiconductor layer 208 may also include n-type impurities. Furthermore, the second conductivity-type semiconductor layer 208 may be electrically connected to the substrate through the electrode 210.

The transparent electrode layer 209 may be stacked on the second conductivity-type semiconductor layer 208. For example, the transparent electrode layer 209 may include a conductive oxide such as indium tin oxide (ITO), indium zinc oxide (IZO), etc.

A plurality of electrodes 210 may be formed and electrically connected to the first conductivity-type semiconductor layer 203 and the substrate 100 or electrically connected to the second conductivity-type semiconductor layer 208 and the substrate 100. By the electrode 210, the light emitting device 200 may be supplied with a current to generate light. The electrode 210 may be formed of Cr, Pt, Au, etc. The plurality of electrodes 210 may include a first electrode 210a and a second electrode 210b.

The first electrode 210a may be electrically connected to the second conductivity-type semiconductor layer 208 and the substrate 100. The second electrode 210b may be electrically connected to the first conductivity-type semiconductor layer 203 and the substrate 100.

The controller 300 may be disposed on the substrate 100 and control the current supplied to a plurality of light emitting devices 200 to change the spectrum of light emitted from the light emitting devices 200. For example, the controller 300 may be a driving device or a driving circuit that controls at least one of a magnitude of a current, a current density, and a current supply time supplied to the plurality of light emitting devices 200 disposed on the substrate 100. By the controller 300, the plurality of light emitting devices 200 may generate light that forms an emission spectrum having a plurality of peaks. Meanwhile, the controller 300 may be implemented by at least one of a computing device including a microprocessor, a switching circuit, a measuring device such as a sensor, and a memory. Since the implementation method thereof is apparent to those skilled in the art, a further detailed description thereof will be omitted.

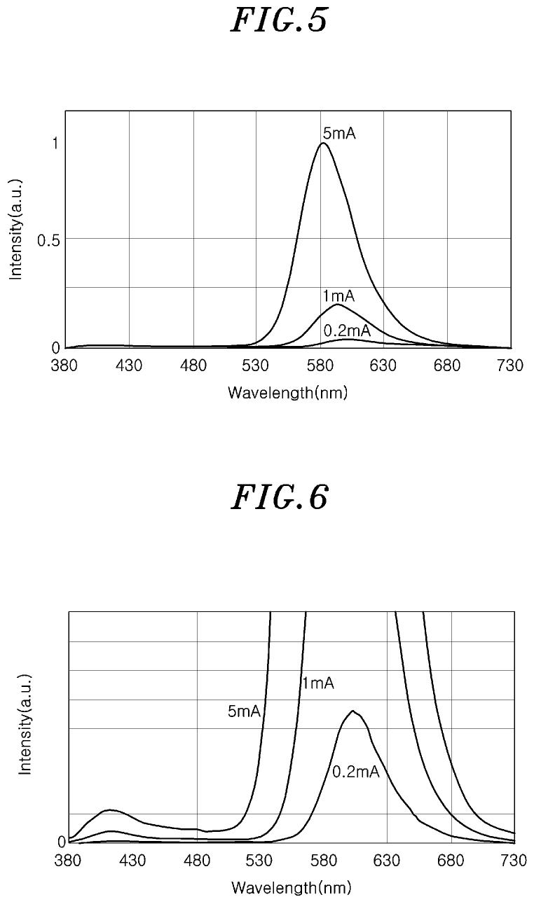

Referring to FIGS. 5 and 6, the plurality of peaks included in the emission spectrum may include a main peak and a sub peak. Therefore, the dominant wavelength of the emission spectrum of the light emitting device may have a different value from the main peak and the sub peak.

In one example, the main peak may be located in a wavelength range longer than 580 nm. An intensity of light at the sub peak may be formed to be lower than an intensity of light at the main peak. The sub peak may be located in a short wavelength range of 400 nm to 430 nm. For example, the sub peak may be located in a wavelength range shorter than 420 nm. In another example, the main peak may have a shorter wavelength than the sub peak. For example, the main peak may be located in a blue region of 440 nm to 480 nm, and the sub peak may be located in a longer wavelength range of 500 nm to 700 nm. In this case, the dominant wavelength may have a value in a region between the main peak and the sub peak.

In another example, the sub peak may be located in a wavelength range of 420 nm to 580 nm. Furthermore, a plurality of sub peaks may be formed. The plurality of sub peaks may be located in different wavelength ranges. The plurality of sub peaks may include a first sub peak and a second sub peak. A wavelength difference between the first sub peak and the second sub peak may be at least 50 nm and at most 200 nm. At least one of the first sub peak and the second sub peak may be located in a different wavelength range from the main peak. A wavelength difference between at least one of the first sub peak and the second sub peak and the main peak may be 150 nm or more. Through this, various colors may be implemented by sufficiently securing a region. In this case, the dominant wavelength may have a value in a region between the main peak and the sub peak.

The controller 300 may control at least one of a current and a current density applied to the light emitting device 200. The controller 300 may increase a current supplied to the light emitting device 200 to increase an intensity of light or a current density at the main peak and the sub peak. For example, the controller 300 may supply a current of 0.2 mA, 1 mA, and 5 mA to the light emitting device 200. When a current supplied to the light emitting device 200 increases, intensities of the main peak and the sub peak increase, and a wavelength of the main peak may shift toward a short-wavelength side. Furthermore, when the current supplied to the light emitting device 200 increases, a ratio of a height to a full width at half maximum in the emission spectrum may also increase. In other words, when the current supplied to the light emitting device 200 increases, a color purity of light emitted from the light emitting device 200 may be improved.

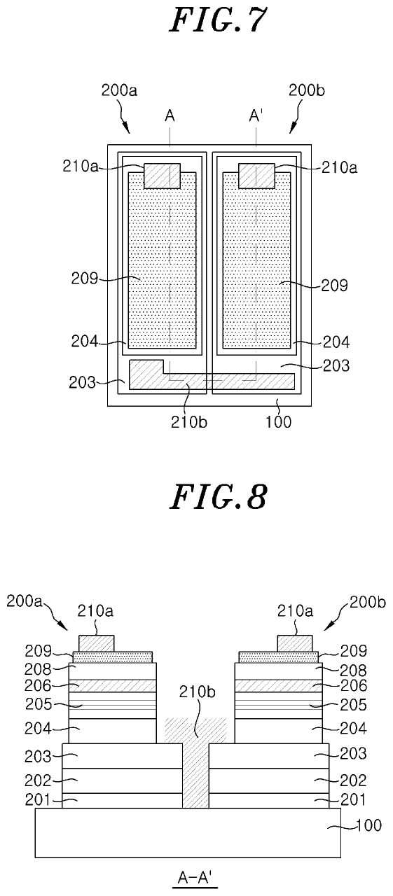

Hereinafter, a light emitting device 200 disposed on the substrate 100 according to a second embodiment will be described with reference to FIGS. 7 and 8.

In describing the second embodiment, there is a difference in that an electrode 210 of a plurality of light emitting devices 200 may be integrally formed, and thus this difference will be mainly described.

A first electrode 210a of a first light emitting device 200a and a first electrode 210a of the second light emitting device 200b may be integrally formed. Furthermore, a second electrode 210b of the first light emitting device 200a and a second electrode 210b of the second light emitting device 200b may be integrally formed. When at least one of the first electrode 210a and the second electrode 210b of the first light emitting device 200a and the second light emitting device 200b is integrally formed, a design difficulty may be lowered.

Furthermore, the first light emitting device 200a and the second light emitting device 200b may include different superlattice layers 205 having different bandgap energies. For example, the superlattice layer 205 of the first light emitting device 200a may include a first superlattice layer 205a, and the superlattice layer 205 of the second light emitting device 200b may include a second superlattice layer 205b. Accordingly, the first light emitting device 200a and the second light emitting device 200b may generate light having different peak wavelengths.

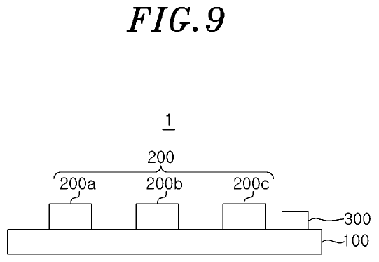

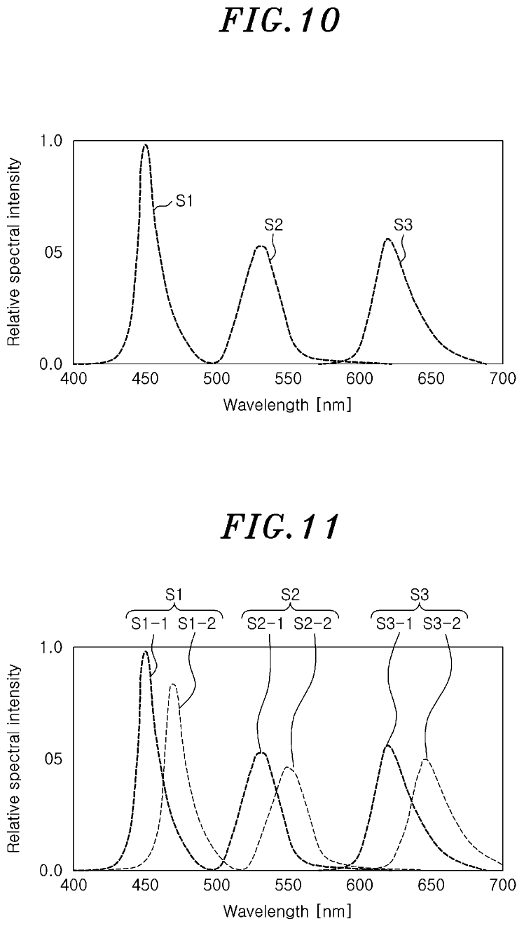

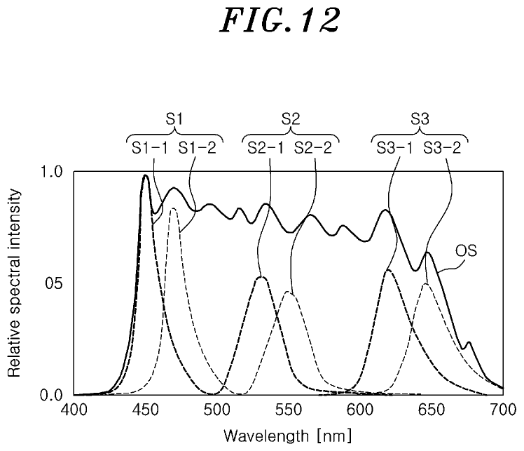

Hereinafter, a light emitting device 200 disposed on the substrate 100 according to a third embodiment will be described with reference to FIGS. 9 to 12.

In describing the third embodiment, there is a difference in that a plurality of light emitting devices 200 include a first light emitting device 200a, a second light emitting device 200b, and a third light emitting device 200c, and thus this difference will be mainly described.

The first light emitting device 200a may generate light that forms a first emission spectrum S1. The first light emitting device 200a may generate light whose main peak wavelength is located between 440 nm and 470 nm. In other words, the first emission spectrum S1 may have a first main peak wavelength located in a blue wavelength region. In this case, the first main peak wavelength may be the peak wavelength in the spectrum excluding a sub peak. Furthermore, the first main peak wavelength may include a plurality of peaks. The plurality of peaks of the first main peak wavelength may include a first main peak and a first sub peak.

The first main peak may be located between 420 nm and 480 nm. In other words, the first main peak may be located in a blue wavelength region. In this case, a dominant wavelength of the first main peak wavelength may be located between 420 nm and 480 nm. The dominant wavelength of the first main peak wavelength is referred to as a first dominant wavelength. The first dominant wavelength may be located between the first sub peak and the first main peak. A wavelength difference between the first sub peak and the first main peak may be less than 10 nm.

At least one first sub peak may be formed in the first spectrum. The first sub peak may be located in a different wavelength band from the first main peak. In other words, the at least one first sub peak may be located in a wavelength band other than the blue wavelength region. For example, the first sub peak may be located in a green wavelength region or a red wavelength region. Furthermore, the first sub peak may have a longer wavelength than the first main peak.

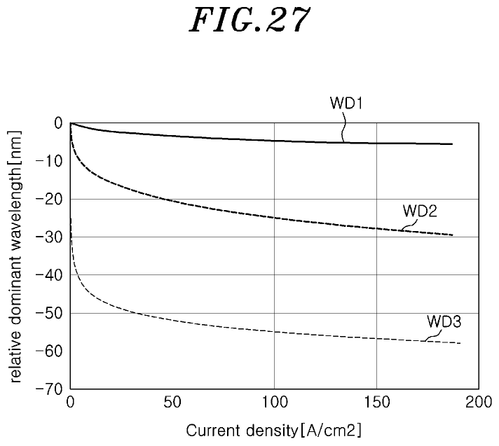

Furthermore, the first emission spectrum S1 may be changed according to a current density supplied to the first light emitting device 200a. The first emission spectrum S1 may be formed as a first-1 emission spectrum S1-1 or a first-2 emission spectrum S1-2 according to the current density. In one embodiment, the first dominant wavelength of the first light emitting device 200a may have a change rate of dominant wavelength for each current density of WD1 shown in FIG. 27 to be described later. Meanwhile, as shown in Equation 1 below, the current density may be the current value according to the area of the light emitting device 200. An area of the light emitting device 200 may be calculated as a product of a horizontal length and a vertical length of the light emitting device 200.

$$Current density ( J ) = \frac{Current value ( I )}{Area of light emitting device ( A )} \qquad ( Equation 1 )$$

The first-1 emission spectrum S1-1 may be formed by light generated from the first light emitting device 200a when a current density supplied to the first light emitting device 200a is greater than a current density supplied to the first light emitting device 200a to form the first-2 emission spectrum S1-2. A wavelength of the first dominant wavelength of the first-1 emission spectrum S1-1 may be smaller than a wavelength of the first dominant wavelength of the first-2 emission spectrum S1-2. Furthermore, an intensity of the first dominant wavelength of the first-1 emission spectrum S1-1 may be greater than an intensity of the first dominant wavelength of the first-2 emission spectrum S1-2.

The first-2 emission spectrum S1-2 may be formed by light generated from the first light emitting device 200a when a current density supplied to the first light emitting device 200a is smaller than a current density of a current supplied to the first light emitting device 200a to form the first-1 emission spectrum S1-1. A wavelength of the first dominant wavelength of the first-2 emission spectrum S1-2 may be greater than the wavelength of the first dominant wavelength of the first-1 emission spectrum S1-1. Furthermore, an intensity at the second dominant wavelength of the first-2 emission spectrum S1-2 may be smaller than an intensity at the second dominant wavelength of the first-1 emission spectrum S1-1.

The second light emitting device 200b may generate light that forms a second emission spectrum S2. For example, a second dominant wavelength of the second light emitting device 200b may have a change rate of dominant wavelength for each current density of WD2 shown in FIG. 27 to be described later. The second light emitting device 200b may generate light whose main peak wavelength is located between 500 nm and 600 nm. In other words, the second emission spectrum S2 may have a second main peak wavelength located in a green wavelength region. In this case, the second main peak wavelength may be a main peak wavelength in a spectrum excluding a sub peak. Furthermore, the second main peak wavelength may have at least one peak. The second main peak wavelength may include a second main peak and a second sub peak, but is not limited thereto.

The second main peak may be located between 500 nm and 600 nm. In other words, the second main peak may be located in a green wavelength region. In this case, a dominant wavelength of the second main peak wavelength may be located between 500 nm and 600 nm. The dominant wavelength of the second main peak wavelength is referred to as a second dominant wavelength. A wavelength difference between the second sub peak and the second main peak may be less than 12 nm. The second dominant wavelength may be a value between the second main peak and the second sub peak.

At least one second sub peak may be formed in the second emission spectrum S2. The second sub peak may be located in a different wavelength band from the second main peak. In other words, the at least one second sub peak may be located in a wavelength band other than the green wavelength region. For example, the second sub peak may be located in a blue wavelength region or a red wavelength region. Furthermore, the second sub peak may have a longer wavelength than the second main peak. In this case, the second dominant wavelength may have a longer wavelength than the second main peak.

Furthermore, the second emission spectrum S2 may be changed according to a current density supplied to the second light emitting device 200b. The second emission spectrum S2 may be formed as a second-1 emission spectrum S2-1 and a second-2 emission spectrum S2-2 according to the current density.

The second-1 emission spectrum S2-1 may be formed by light generated from the second light emitting device 200b when a current density supplied to the second light emitting device 200b is greater than a current density supplied to the second light emitting device 200a to form the second-2 emission spectrum S2-2. A wavelength of the second dominant wavelength of the second-1 emission spectrum S2-1 may be smaller than a wavelength of the second dominant wavelength of the second-2 emission spectrum S2-2. Furthermore, an intensity at the second dominant wavelength of the second-1 emission spectrum S2-1 may be greater than an intensity at the second dominant wavelength of the second-2 emission spectrum S2-2. The intensity of the second dominant wavelength of the second-1 emission spectrum S2-1 may be formed to be smaller than the intensity at the first dominant wavelength of the first-1 emission spectrum S1-1.

The second-2 emission spectrum S2-2 may be formed by light generated from the second light emitting device 200b when a current density supplied to the second light emitting device 200b is smaller than a current density supplied to the second light emitting device 200b to form the second-1 emission spectrum S2-1. A wavelength of the second dominant wavelength of the second-2 emission spectrum S2-2 may be greater than the wavelength of the second dominant wavelength of the second-1 emission spectrum S2-1. Furthermore, an intensity at the second dominant wavelength of the second-2 emission spectrum S2-2 may be smaller than the intensity at the second dominant wavelength of the second-1 emission spectrum S2-1. The intensity of the second dominant wavelength of the second-2 emission spectrum S2-2 may be formed to be smaller than the intensity at the first dominant wavelength of the first-2 emission spectrum S1-2.

The third light emitting device 200c may generate light that forms a third emission spectrum S3. The third light emitting device 200c may generate light whose main peak wavelength is located between 600 nm and 670 nm. In other words, the third emission spectrum S3 may have a third main peak wavelength located in a red wavelength region. In this case, the third main peak wavelength may be a main peak wavelength in a spectrum excluding a sub peak. Furthermore, the third main peak wavelength may include a plurality of peaks. The plurality of peaks of the third main peak wavelength may include a third main peak and a third sub peak, but is not limited thereto. In one embodiment, a third dominant wavelength of the third light emitting device 200c may have a change rate of dominant wavelength for each current density of WD3 shown in FIG. 27 to be described later.

The third main peak may be located between 600 nm and 670 nm. In other words, the third main peak may be located in a red wavelength region. In this case, a dominant wavelength of the third main peak wavelength may be located between 600 nm and 670 nm. The dominant wavelength of the third main peak wavelength is referred to as a third dominant wavelength. The third dominant wavelength may be located between the third main peak and the third sub peak. Furthermore, a difference between the third sub peak and the third main peak may be less than 15 nm.

At least one third sub peak may be formed in the third spectrum. The third sub peak may be located in a different wavelength band from the third main peak. In other words, the at least one third sub peak may be located in a wavelength band other than the red wavelength region. For example, the third sub peak may be located in a blue wavelength region or a green wavelength region.

Furthermore, the third emission spectrum S3 may be changed according to a current density supplied to the third light emitting device 200c. The third emission spectrum S3 may be formed as a third-1 emission spectrum S3-1 and a third-2 emission spectrum S3-2 according to the current density.

The third-1 emission spectrum S3-1 may be formed by light generated from the third light emitting device 200c when a current density supplied to the third light emitting device 200c is greater than a current density supplied to the third light emitting device 200c to form the third-2 emission spectrum S3-2. A wavelength of the third dominant wavelength of the third-1 emission spectrum S3-1 may be smaller than a wavelength of the third dominant wavelength of the third-2 emission spectrum S3-2. Furthermore, an intensity at the third dominant wavelength of the third-1 emission spectrum S3-1 may be greater than an intensity at the third dominant wavelength of the third-2 emission spectrum S3-2.

The third-2 emission spectrum S3-2 may be formed by light generated from the third light emitting device 200c when a current density supplied to the third light emitting device 200c is smaller than a current density supplied to the third light emitting device 200c to form the third-1 emission spectrum S2-1. A wavelength of the third dominant wavelength of the third-2 emission spectrum S3-2 may be greater than the wavelength of the third dominant wavelength of the third-1 emission spectrum S3-1. Furthermore, an intensity at the third dominant wavelength of the third-2 emission spectrum S3-2 may be smaller than the intensity at the third dominant wavelength of the third-1 emission spectrum S3-1.

The controller 300 may control the current such that a current density supplied to the plurality of light emitting devices 200 varies over time. By the controller 300, each of the plurality of light emitting devices 200 may generate light of a different dominant wavelength. Furthermore, by the controller 300, the light emitting apparatus 1 may generate light having an emission spectrum in a white wavelength band in a certain time interval by a current that changes over time. The light emitting apparatus 1 may be driven by a Pulse Width Modulation (PWM) method. A frequency of the current may be 60 Hz or more. A color of light generated from the light emitting apparatus 1 may appear continuous to a user.

When a current whose magnitude changes for a predetermined time is supplied from the controller 300 to the plurality of light emitting devices 200, emission spectra of the plurality of light emitting devices 200 may at least partially overlap. In other words, an overlapped spectrum OS may be formed as at least some of the first emission spectrum S1, the second emission spectrum S2, and the third emission spectrum S3 overlap.

The overlapped spectrum OS may have a white color temperature. A plurality of peaks and valleys may be formed in the overlapped spectrum OS. A difference between a peak and a valley of the overlapped spectrum OS may be formed to be smaller than a difference between a peak and a valley formed in each of the plurality of emission spectra. By the overlapped spectrum OS, the light emitting apparatus 1 may improve the CRI and generate light similar to sunlight. The Color Rendering Index (CRI) of the overlapped spectrum OS may have a value of Ra 70 or higher. The overlapped spectrum OS may satisfy Rf 70 or higher in a Color Fidelity item that evaluates a degree of similarity to sunlight. More preferably, the Color Rendering Index of the overlapped spectrum OS may have a value of Ra 80 or higher. The overlapped spectrum OS may satisfy Rf 80 or higher in the Color Fidelity item.

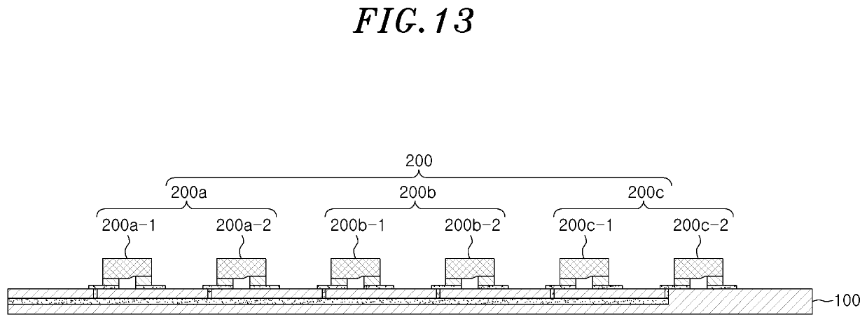

Hereinafter, a light emitting apparatus 1 according to a fourth embodiment will be described with reference to FIG. 13.

In the light emitting apparatus 1 according to the fourth embodiment, there is a difference in that at least one of the first light emitting device 200a, the second light emitting device 200b, and the third light emitting device 200c may include at least one light emitting part to improve the Color Rendering Index of the overlapped spectrum OS, and thus this difference will be mainly described.

The first light emitting device 200a may include a first-1 light emitting part 200a-1 and a first-2 light emitting part 200a-2. The first-1 light emitting part 200a-1 and the first-2 light emitting part 200a-2 may have different first dominant wavelengths. For example, when the first-1 light emitting part 200a-1 emits a first-1 emission spectrum S1-1, the first-2 light emitting part 200a-2 may emit a first-2 emission spectrum S1-2. That is, the first-2 light emitting part 200a-2 may have a first dominant wavelength that is longer than the first dominant wavelength of the first-1 light emitting part 200a-1.

The first-1 light emitting part 200a-1 may be driven at a higher current density than the first-2 light emitting part 200a-2. Through this, the first-2 light emitting part 200a-2 may have a first dominant wavelength of a first longer wavelength than the first-1 light emitting part 200a-1. In this case, the controller 300 may adjust an amount of current such that the first-2 light emitting part 200a-2 is driven at a lower current density than the first-1 light emitting part 200a-1.

The second light emitting device 200b may include a second-1 light emitting part 200b-1 and a second-2 light emitting part 200b-2. In this case, the second-1 light emitting part 200b-1 and the second-2 light emitting part 200b-2 may have different second dominant wavelengths. For example, when the second-1 light emitting part 200b-1 emits a second-1 emission spectrum S2-1, the second-2 light emitting part 200b-2 may emit a second-2 emission spectrum S2-2. That is, the second-2 light emitting part 200b-2 may have a second dominant wavelength that is longer than the second dominant wavelength of the second-1 light emitting part 200b-1.

In this case, the second-1 light emitting part 200b-1 may be driven at a higher current density than the second-2 light emitting part 200b-2. Through this, the second-2 light emitting part 200b-2 may have a second dominant wavelength that is longer than the second dominant wavelength of the second-1 light emitting part 200b-1. In this case, the controller 300 may adjust an amount of current such that the second-2 light emitting part 200b-2 is driven at a lower current density than the second-1 light emitting part 200b-1.

Furthermore, the third light emitting device 200c may include a third-1 light-emitting part 200c-1 and a third-2 light-emitting part 200c-2. In this case, the third-1 light-emitting part 200c-1 and the third-2 light-emitting part 200c-2 may have different third dominant wavelengths. For example, when the third-1 light-emitting part 200c-1 emits a third-1 emission spectrum S3-1, the third-2 light-emitting part 200c-2 may emit a third-2 emission spectrum S3-2. That is, the third-2 light-emitting part 200c-2 may have a third dominant wavelength that is longer than the third dominant wavelength of the third-1 light-emitting part 200c-1.

In this case, the third-1 light-emitting part 200c-1 may be driven at a higher current density than the third-2 light-emitting part 200c-2. Through this, the third-2 light-emitting part 200c-2 may have a dominant wavelength that is longer than that of the third-1 light-emitting part 200c-1. In this case, the controller 300 may adjust an amount of current such that the third-2 light-emitting part 200c-2 is driven at a lower current density than the third-1 light-emitting part 200c-1.

Hereinafter, a first example in which the controller 300 supplies a first current waveform to at least one of a plurality of light emitting devices 200 will be described with reference to FIG. 14.

The controller 300 may control a current such that a first current waveform whose magnitude decreases over time is supplied to a plurality of light emitting devices 200. The controller 300 may supply the first current waveform for a predetermined current supply time. The current supply time may include a plurality of time intervals having different start time values. The plurality of time intervals may have a longer time length as a start time value becomes larger. Furthermore, the controller 300 may form the first current waveform by controlling the current such that a current supplied to the plurality of light emitting devices 200 decreases as a time interval has a larger start time value.

For example, the plurality of time intervals may include a first time interval t1, a second time interval t2, a third time interval t3, a fourth time interval t4, a fifth time interval t5, a sixth time interval t6, and a seventh time interval t7. A start time value of the first time interval t1 may be the smallest among the plurality of time intervals. A first time length of the first time interval t1 may be the shortest among the plurality of time intervals. A start time value of the seventh time interval t7 may be the largest among the plurality of time intervals. A second time length of the seventh time interval t7 may be the longest among a plurality of time intervals. In the first time interval t1, a first current value, which is the largest among the plurality of time intervals, may be supplied to the plurality of light emitting devices 200 for the shortest time among the plurality of time intervals. In the seventh time interval t7, a second current value, which is the smallest, may be supplied to the plurality of light emitting devices 200 for the longest time among the plurality of time intervals. Furthermore, an amount of electricity or charge supplied in the first time interval t1 and the seventh time interval t7 may be similar. The amount of electricity may be a value obtained by multiplying a time length and a current intensity value. In other words, even if an intensity of a current supplied to the plurality of light emitting devices 200 decreases as time passes, luminous energy may be maintained, so an amount of light produced per hour by the light emitting apparatus 1 may be maintained. For example, even if a spectrum of light generated from the light emitting apparatus 1 is formed at a long wavelength due to a low current, a luminous energy of the light emitting apparatus 1 may be maintained constant by increasing a current supply time to the light emitting apparatus 1.

A difference in an amount of electricity between the first time interval t1 and the seventh time interval t7 may be less than 10%. A ratio of a first time length of the first time interval t1 and a current supplied in the first time interval t1 may be similar to a ratio of a second time length of the seventh time interval t7 and a current supplied in the seventh time interval t7, and a difference thereof may be less than 10%. A duty of the current may vary for each interval. As a magnitude of the current decreases, the duty may be increased to maintain a brightness. Furthermore, a ratio of an amount of current decrease from the first time interval t1 to the seventh time interval t7 may be similar to a ratio of an amount of time length increase from the first time interval t1 to the seventh time interval t7, and a difference thereof may be less than 10%. A ratio between the first time length and the first current value and a ratio between the first time length and the second current value may be similar to each other, and a difference thereof may be less than 10%. Through this, a luminous energy of the light emitting apparatus 1 may be maintained constant even with a change in a time interval.

In addition, the first current value, the first time length, the second current value, and the second time length may satisfy Equation 1 below.

$$\frac{first current - second current value}{first current value} \approx \frac{second time length - first time length}{second time length} \qquad ( Equation 1 )$$

Furthermore, in the first time interval t1, light that forms a first-1 emission spectrum S1-1, a second-1 emission spectrum S2-1, or a third-1 emission spectrum S3-1 may be generated from the light emitting device 200.

In the seventh time interval t7, light that forms a first-2 emission spectrum S1-2, a second-2 emission spectrum S2-2, or a third-2 emission spectrum S3-2 may be generated from the light emitting device 200.

An amount of electricity in at least one of the second time interval t2, the third time interval t3, the fourth time interval t4, the fifth time interval t5, and the sixth time interval t6 located between the first time interval t1 and the seventh time interval t7 may be similar to an amount of electricity in the first time interval t1 and the seventh time interval t7. The difference may be less than 10%. Through such a small rectification difference, a wavelength overlap region may be widened to increase a color reproduction rate. Hereinafter, the second time interval t2 will be described as a reference, but is not limited thereto.

In the second time interval t2, light that forms an emission spectrum between the first-1 emission spectrum S1-1 and the first-2 emission spectrum S1-2, an emission spectrum between the second-1 emission spectrum S2-1 and the second-2 emission spectrum S2-2, or an emission spectrum between the third-1 emission spectrum S3-1 and the third-2 emission spectrum S3-2 may be generated from the light emitting device 200. Through this, spectra that change for each time interval may be overlapped to emit white light.

Meanwhile, the first current waveform may have a continuous form, but is not limited thereto. The first current waveform may be supplied to the light emitting device 200 discontinuously. Through this, power consumption may be saved. Furthermore, the first current waveform may be formed to have a constant current value in a time interval, but is not limited thereto. In other words, the controller 300 may also control the current such that the current decreases as time passes within at least some of the plurality of start intervals. In this case, a duty cycle of the first current waveform may be 60 Hz or more. Through this, a user may not perceive flickering, and overlapping of wavelengths is possible.

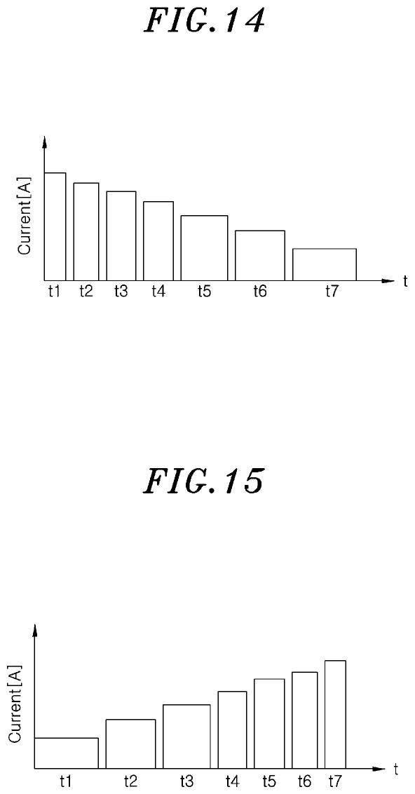

Hereinafter, a second example in which the controller 300 supplies a second current waveform to at least one of a plurality of light emitting devices 200 will be described with reference to FIG. 15.

The controller 300 may control the current such that a second current waveform whose magnitude increases over time is supplied to the plurality of light emitting devices 200. The controller 300 may supply the second current waveform for a predetermined current supply time. The current supply time may include a plurality of time intervals having different start time values. The plurality of time intervals may have a smaller time length as a start time value becomes larger. Furthermore, the controller 300 may form the second current waveform by controlling the current such that a current supplied to the plurality of light emitting devices 200 increases as a time interval has a larger start time value.

For example, the plurality of time intervals may include a first time interval t1, a second time interval t2, a third time interval t3, a fourth time interval t4, a fifth time interval t5, a sixth time interval t6, and a seventh time interval t7. A start time value of the first time interval t1 may be the smallest among the plurality of time intervals. A first time length of the first time interval t1 may be the longest among the plurality of time intervals. A start time value of the seventh time interval t7 may be the largest among the plurality of time intervals. A second time length of the seventh time interval t7 may be the shortest among the plurality of time intervals. In the first time interval t1, a first current value, which is the smallest, may be supplied to the plurality of light emitting devices 200 for the longest time among the plurality of time intervals. In the seventh time interval t7, a large second current value may be supplied to the plurality of light emitting devices 200 for the shortest time among the plurality of time intervals. Furthermore, an amount of electricity supplied in the first time interval t1 and the seventh time interval t7 may be similar. In other words, even if a current supplied to the plurality of light emitting devices 200 increases as time passes, luminous energy may be maintained, so an amount of light produced per hour by the light emitting apparatus 1 may be maintained. That is, even if a spectrum of light generated from the light emitting apparatus 1 is formed at a short wavelength by adjusting the current, a luminous energy of the light emitting apparatus 1 may be maintained constant.

A difference in an amount of electricity between the first time interval t1 and the seventh time interval t7 may be less than 10%. A ratio of a first time length of the first time interval t1 and a current supplied in the first time interval t1 may be similar to a ratio of a second time length of the seventh time interval t7 and a current supplied in the seventh time interval t7, and a difference thereof may be less than 10%. A duty of the current may vary for each interval. As a magnitude of the current increases, the duty may be decreased to maintain a brightness. Furthermore, a ratio of an amount of current increase from the first time interval t1 to the seventh time interval t7 may be similar to a ratio of an amount of time length decrease from the first time interval t1 to the seventh time interval t7, and a difference thereof may be less than 10%. A ratio between the first time length and the first current value and a ratio between the first time length and the second current value may be similar to each other, and a difference thereof may be less than 10%.

In addition, the first current value, the first time length, the second current value, and the second time length may satisfy Equation 2 below.

$$\frac{second current - first current value}{second current value} \approx \frac{first time length - second time length}{first time length} \qquad ( Equation 2 )$$

In the first time interval t1, a first-2 emission spectrum S1-2, a second-2 emission spectrum S2-2, or a third-2 emission spectrum S3-2 may be generated from the light emitting device 200.

In the seventh time interval t7, light that forms a first-1 emission spectrum S1-1, a second-1 emission spectrum S2-1, or a third-1 emission spectrum S3-1 may be generated from the light emitting device 200.

An amount of electricity in at least one of the second time interval t2, the third time interval t3, the fourth time interval t4, the fifth time interval t5, and the sixth time interval t6 located between the first time interval t1 and the seventh time interval t7 may be similar to an amount of electricity in the first time interval t1 and the seventh time interval t7, and a difference thereof may be less than 10%. Hereinafter, the second time interval t2 will be described as a reference, but is not limited thereto.

In the second time interval t2, light that forms an emission spectrum between the first-1 emission spectrum S1-1 and the first-2 emission spectrum S1-2, an emission spectrum between the second-1 emission spectrum S2-1 and the second-2 emission spectrum S2-2, or an emission spectrum between the third-1 emission spectrum S3-1 and the third-2 emission spectrum S3-2 may be generated from the light emitting device 200.

Meanwhile, the second current waveform may have a continuous form, but is not limited thereto. The second current waveform may be supplied to the light emitting device 200 discontinuously. By the second current waveform, the light emitting device 200 may be driven discontinuously, so driving energy may be saved.

Hereinafter, a third example in which the controller 300 supplies a third current waveform to at least one of a plurality of light emitting devices 200 will be described with reference to FIG. 16.

The controller 300 may control a current such that a third current waveform for increasing an amount of electricity supplied to the plurality of light emitting devices 200 over time is supplied to the plurality of light emitting devices 200. The controller 300 may control the current such that a magnitude of the current increases even within a plurality of time intervals. By the controller 300, a wavelength of the light emitting apparatus 1 may be adjusted while a luminous energy is maintained constant. An amount of electricity in a first time interval t1 in which a lowest first current value is supplied and an amount of electricity in a seventh time interval t7 in which a highest second current value is supplied may be similar to each other, and a difference thereof may be less than 10%. Through this, a natural color change may be implemented. A current change rate in the first time interval t1 may be smaller than a current change rate in the seventh time interval t7. In other words, the third current waveform may be formed to have different slopes in a plurality of time intervals. A slope of a current in the plurality of time intervals may have a lowest slope in the first time interval t1 and a largest slope in the seventh time interval t7. A center of a slope of a current in each of the plurality of time intervals may coincide with a center of a time length of each of the plurality of time intervals. Furthermore, a current value at a start time value of the first time interval t1 may be smaller than a current value at an end time value of the first time interval t1. An average of a current at a start time value and an end time value in a first time interval t1 may be equal to a current value at a center of a first time length.

A ratio of a first time length of the first time interval t1 and a current supplied in the first time interval t1 may be similar to a ratio of a second time length of the seventh time interval t7 and a current supplied in the seventh time interval t7, and a difference thereof may be less than 10%. A duty of the current may vary for each interval. As the current decreases, the duty may be increased to maintain a brightness. Furthermore, a ratio of an amount of current increase from the first time interval t1 to the seventh time interval t7 may be similar to a ratio of an amount of time length decrease from the first time interval t1 to the seventh time interval t7, and a difference thereof may be less than 10%. When an amount of decrease in each interval is controlled to be less than 10%, natural color control is possible.

In the first time interval t1, light that forms an emission spectrum between the first-1 emission spectrum S1-1 and the first-2 emission spectrum S1-2, an emission spectrum between the second-1 emission spectrum S2-1 and the second-2 emission spectrum S2-2, or an emission spectrum between the third-1 emission spectrum S3-1 and the third-2 emission spectrum S3-2 may be generated from the light emitting device 200.

Furthermore, in the seventh time interval t7, light that forms an emission spectrum between the first-1 emission spectrum S1-1 and the first-2 emission spectrum S1-2, an emission spectrum between the second-1 emission spectrum S2-1 and the second-2 emission spectrum S2-2, or an emission spectrum between the third-1 emission spectrum S3-1 and the third-2 emission spectrum S3-2 may be generated from the light emitting device 200.

An emission spectrum of light generated in the first time interval t1 may be positioned closer to a first-1 emission spectrum S1-1, a second-1 emission spectrum S2-1, or a third-1 emission spectrum S3-1 than an emission spectrum of light generated in a seventh time interval t7.

Meanwhile, the third current waveform is expressed in a continuous form, but is not limited thereto. The third current waveform may be supplied to the light emitting device 200 discontinuously. By the third current waveform, the light emitting device 200 may be driven discontinuously, so power consumption may be saved.

The controller 300 may perform control such that different current waveforms are supplied to the plurality of light emitting devices 200. For example, the controller 300 may perform control such that a first current waveform is supplied to a first light emitting device 200a and a second current waveform or a third current waveform is supplied to a second light emitting device 200b. The plurality of light emitting devices 200 may be supplied with different current waveforms during a current supply time to form light of an overlapped spectrum, so that white light with an improved CRI may be implemented.

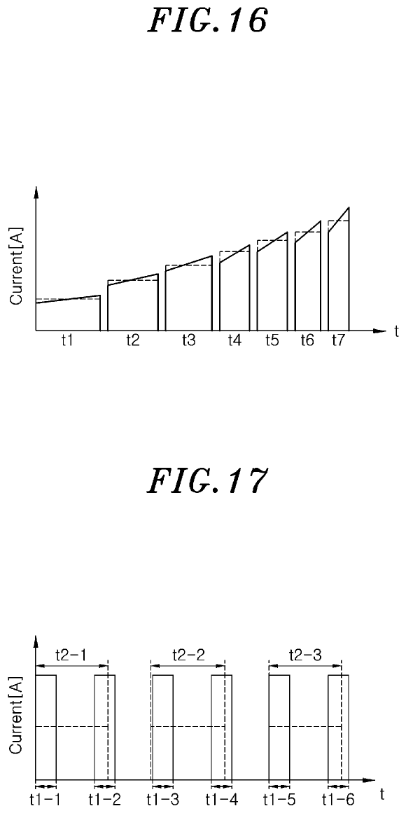

Hereinafter, a fourth example in which the controller 300 supplies a fourth current waveform to a first light emitting device 200a and a fifth current waveform to a second light emitting device 200c will be described with reference to FIG. 17.

The fourth current waveform may be formed such that a current is supplied to the first light emitting device 200a with a preset first current supply period. The fifth current waveform may be formed such that a current is supplied to the second light emitting device 200b with a predetermined second current supply period.

Furthermore, a time during which a current is supplied in the first current supply period may be shorter than a time during which a current is supplied in the second current supply period. Furthermore, a magnitude of a current in the first current supply period may be formed to be larger than a current supplied in the second current supply period.

The first light emitting device 200a may generate light that forms a first-1 emission spectrum S1-1, a second-1 emission spectrum S2-1, and a third-1 emission spectrum S3-1. Furthermore, the second light emitting device 200b may generate light that forms a first-2 emission spectrum S1-2, a second-2 emission spectrum S2-2, and a third-2 emission spectrum S3-2. Through this, an emission spectrum may be efficiently overlapped, and a difficulty in implementing white light may be lowered.

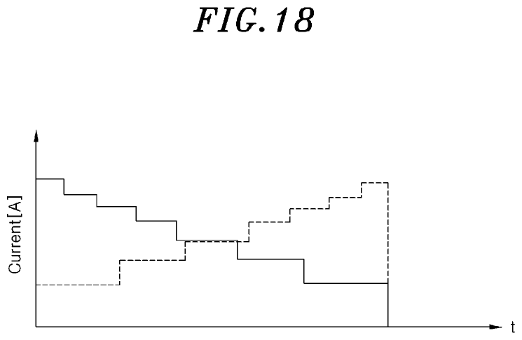

Hereinafter, a fifth example in which the controller 300 supplies a first current waveform to a first light emitting device 200a and a second current waveform to a second light emitting device 200b will be described with reference to FIG. 18.

A current supplied to the first light emitting device 200a may decrease in magnitude as time passes. A current supplied to the second light emitting device 200b may increase in magnitude as time passes. At a driving start time, the first light emitting device 200a may generate light that forms a spectrum of one of a first-1 emission spectrum S1-1, a second-1 emission spectrum S2-1, or a third-1 emission spectrum S3-1. Furthermore, at the driving start time, the second light emitting device 200b may generate light that forms a spectrum of at least one of a first-2 emission spectrum S1-2, a second-2 emission spectrum S2-2, or a third-2 emission spectrum S3-2.

As a driving time passes, the first light emitting device 200a may generate light that forms a spectrum similar to one of a first-2 emission spectrum S1-2, a second-2 emission spectrum S2-2, or a third-2 emission spectrum S3-2. Furthermore, as the driving time passes, the second light emitting device 200b may emit a spectrum similar to one of a second-1 emission spectrum S2-1 or a third-1 emission spectrum S3-1. In other words, a wavelength of light generated from the first light emitting device 200a may become longer as time passes, and a wavelength of light generated from the second light emitting device 200b may become shorter as a driving time passes. A luminous intensity of light emitted from the first light emitting device 200a may increase as time passes, and a luminous intensity of the second light emitting device 200b may decrease as time passes.

Furthermore, as the driving time passes, a difference in luminous intensity between the first light emitting device 200a and the second light emitting device 200b may be reduced stepwise. In addition, as the driving time passes, a difference in luminous intensity between the first light emitting device 200a and the second light emitting device 200b may be increased stepwise.

By the first light emitting device 200a and the second light emitting device 200b, white light with an improved CIR value may be implemented. An amount of electricity of the first light emitting device 200a and the second light emitting device 200b may be the same, so an amount of light produced per hour by the first light emitting device 200a and the second light emitting device 200b may be maintained. That is, a sum of luminous energy over time emitted from the first light emitting device 200a and the second light emitting device 200b may be maintained constant by adjusting the current.

Hereinafter, a sixth example in which the controller 300 supplies a sixth current waveform to at least one of a plurality of light emitting devices 200 will be described with reference to FIG. 19.

The controller 300 may control a current such that a sixth current waveform in which a current is supplied with a magnitude of a first current density J₁ is supplied to one of a plurality of light emitting devices 200. The controller 300 may supply the sixth current waveform for a predetermined driving time. The sixth current waveform may be driven with the same first current density J₁ during a current supply time (Ta₁, Ta₃, . . . , Ta₂ₙ₊₁). In this case, the sixth current waveform may have a first charge density per unit area C1. The first charge density per unit area C1 may be represented by Equation 3 below.

$$C 1 = {J}_{1} \times {Ta}_{1} \qquad ( Equation 3 )$$

The first charge density per unit area C1 may be constant during the current supply time (Ta₁, Ta₃, . . . , Ta₂ₙ₊₁).

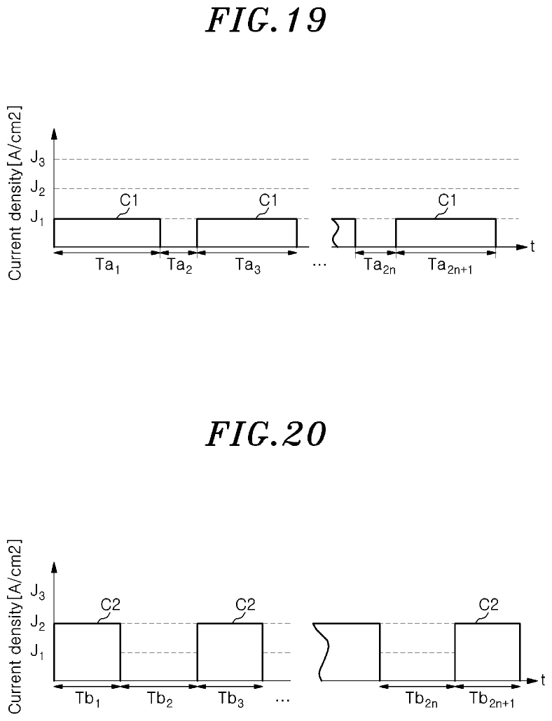

Hereinafter, a seventh example in which the controller 300 supplies a seventh current waveform to at least one of a plurality of light emitting devices 200 will be described with reference to FIG. 20.

The controller 300 may control a current such that a seventh current waveform in which a current is supplied with a second current density J₂ greater than the above-described first current density J₁ is supplied to at least one of the plurality of light emitting devices 200. The controller 300 may supply the seventh current waveform for a predetermined driving time. The seventh current waveform may be driven with the same second current density J₂ during a current supply time (Tb₁, Tb₃, . . . , Tb₂ₙ₊₁). In this case, the seventh current waveform may have a second charge density per unit area C2. The second charge density per unit area C2 may be represented by Equation 4 below.

$$C 2 = {J}_{2} \times {Tb}_{1} \qquad ( Equation 4 )$$

The second charge density per unit area C2 may be constant during the current supply time (Tb₁, Tb₃, . . . , Tb₂ₙ₊₁).

In this case, the second charge density per unit area C2 may be similar to the first charge density per unit area C1. A difference between the first charge density per unit area C1 and the second charge density per unit area C2 may be less than 10%. The first charge density per unit area C1 and the second charge density per unit area C2 may be represented by Equation 5 below.

$$90 \% \leq C 1 \div C 2 \leq 110 \% \qquad ( Equation 5 )$$

Through this, a charge amount per unit time of a light emitting device 200 driven by the sixth current waveform and a light emitting device 200 driven by the seventh current waveform may be the same, so a brightness of the light emitting device 200 driven by the sixth current waveform and a brightness of the light emitting device 200 driven by the seventh current waveform may be perceived as the same. When the difference is less than 90% or greater than 110%, the brightness may be perceived as different, and thus light uniformity may be degraded.

The first current density J₁ may be smaller than the second current density J₂. Furthermore, each of the current supply times (Tb₁, Tb₃, . . . , Tb₂ₙ₊₁) of the seventh current waveform may be shorter than each of the current supply times (Tb₁, Tb₃, . . . . Tb₂ₙ₊₁) of the sixth current waveform. Furthermore, the current supply time (Tb₁, Tb₃, . . . , Tb₂ₙ₊₁) of the seventh current waveform and the current supply time (Tb₁, Tb₃, . . . , Tb₂ₙ₊₁) of the sixth current waveform may be represented by Equation 6 below.

$$0.9 \leq \frac{{J}_{1} \times {Ta}_{2 n + 1}}{{J}_{2} \times {Tb}_{2 n + 1}} \leq 1.1 \qquad ( Equation 6 )$$

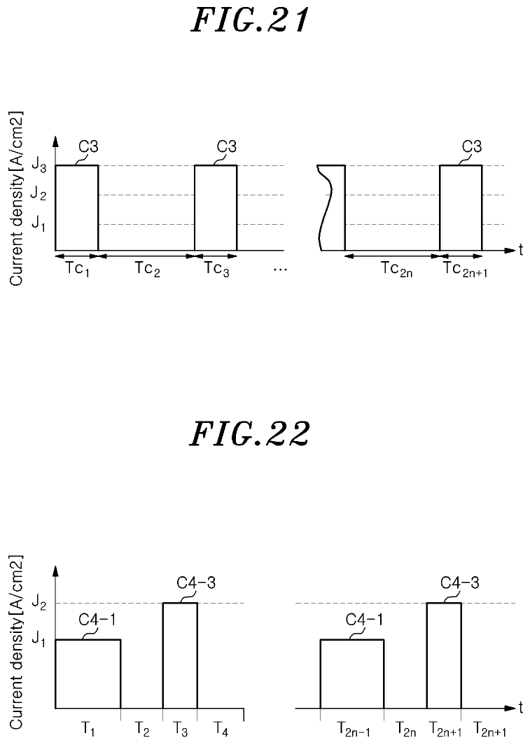

Hereinafter, an eighth example in which the controller 300 supplies an eighth current waveform to at least one of a plurality of light emitting devices 200 will be described with reference to FIG. 21.

The controller 300 may control a current such that an eighth current waveform in which a current is supplied with a magnitude of a third current density J₃ is supplied to at least one of the plurality of light emitting devices 200. The controller 300 may supply the eighth current waveform for a predetermined driving time. The eighth current waveform may be driven with the same third current density J₃ during a current supply time (Tc1, Tc3, . . . , Tc2n+1). In this case, the eighth current waveform may have a third charge density per unit area C3. The third charge density per unit area C3 may be represented by Equation 7 below.

$$C 3 = {J}_{3} \times {Tc}_{1} \qquad ( Equation 7 )$$

The third charge density per unit area C3 may be constant during the current supply time (Tc1, Tc3, . . . , Tc2n+1).

In this case, the third charge density per unit area C3 may be similar to the second charge density per unit area C2. In this case, a difference between the second charge density per unit area C2 and the third charge density per unit area C3 may be less than 10%. The third charge density per unit area C3 and the second charge density per unit area C2 may be represented by Equation 8 below.

$$0.9 \leq C 2 \div C 3 \leq 1.1 \qquad ( Equation 8 )$$

Through this, a charge amount per unit time of a light emitting device 200 driven by the eighth current waveform and a light emitting device 200 driven by the seventh current waveform may be the same, so a brightness of the light emitting device 200 driven by the seventh current waveform and a brightness of the light emitting device 200 driven by the eighth current waveform may be perceived as the same.

The third current density J₃ may be greater than the second current density J₂. Furthermore, each of the current supply times (Ta₁, Ta₃, . . . , Ta₂ₙ₊₁) of the eighth current waveform may be shorter than each of the current supply times (Ta₁, Ta₃, . . . . Ta₂ₙ₊₁) of the seventh current waveform. The current supply time (Ta₁, Ta₃, . . . , Ta₂ₙ₊₁) of the eighth current waveform and the current supply time (Ta₁, Ta₃, . . . , Ta₂ₙ₊₁) of the seventh current waveform may be represented by Equation 9 below.

$$0.9 \leq \frac{{J}_{3} \times {Tc}_{2 n + 1}}{{J}_{2} \times {Tb}_{2 n + 1}} \leq 1.1 \qquad ( Equation 9 )$$

Furthermore, the third charge density per unit area C3 may be similar to the first charge density per unit area C1. In this case, a difference between the first charge density per unit area C1 and the third charge density per unit area C3 may be less than 10%. In this case, each of the current supply times (Ta₁, Ta₃, . . . , Ta₂ₙ₊₁) of the eighth current waveform may be shorter than each of the current supply times (Ta₁, Ta₃, . . . , Ta₂ₙ₊₁) of the sixth current waveform. The current supply time (Ta₁, Ta₃, . . . . Ta₂ₙ₊₁) of the eighth current waveform and the current supply time Tb₁, Tb₃, . . . . Tb₂ₙ₊₁) of the sixth current waveform may be represented by Equation 10 below.

$$0.9 \leq \frac{{J}_{3} \times {Tc}_{2 n + 1}}{{J}_{1} \times {Ta}_{2 n + 1}} \leq 1.1 \qquad ( Equation 10 )$$

Hereinafter, a ninth example in which the controller 300 supplies a ninth current waveform to at least one of a plurality of light emitting devices 200 will be described with reference to FIG. 22.

The controller 300 may control a current such that a ninth current waveform in which a current density varies over time is supplied to at least one of a plurality of light emitting devices 200. The controller 300 may supply the ninth current waveform for a predetermined current supply time. The current supply time may include a plurality of time intervals having different start time values. Furthermore, the plurality of time intervals may have a shorter time length as a current density becomes higher. In this case, a charge density per unit area for each interval may be the same. Furthermore, the plurality of time intervals may have a longer time length as the current density becomes lower. For example, any one of the plurality of light emitting devices 200 may be driven with a first current density J₁ during a first time interval T₁ and have a fourth-1 charge density per unit area C4-1. Furthermore, another one of the plurality of light emitting devices 200 may be driven with a second current density J₂ during a third time interval T₃ and have a fourth-3 charge density per unit area C4-3. The fourth-3 charge density per unit area C4-3 may have an area similar to the fourth-1 charge density per unit area C4-1. A difference between the fourth-3 charge density per unit area C4-3 and the fourth-1 charge density per unit area C4-1 may be less than 10%. Through this, a luminous intensity of the light emitting device 200 may be maintained constant during each time interval. In this case, at least one of the plurality of light emitting devices 200 may have a repeated charge density. That is, any one of the plurality of light emitting devices 200 may be driven with the first current density J₁ during a 2n−1th time interval T₂ₙ₊₁ and have the fourth-1 charge density per unit area C4-1. Furthermore, another one of the plurality of light emitting devices 200 may be driven with the second current density J₂ during a 2n+1th time interval T₂ₙ₊₁ and have the fourth-3 charge density per unit area C4-3. In this case, a difference between the fourth-1 charge density per unit area C4-1 and the fourth-3 charge density per unit area C4-3 may be less than 10%. The fourth-1 charge density per unit area C4-1 and the fourth-3 charge density per unit area C4-3 may be represented by Equation 11 below.

$$0.9 \leq \frac{{J}_{2} \times {T}_{2 n + 1}}{{J}_{1} \times {T}_{2 n - 1}} \leq 1.1 \qquad ( Equation 11 )$$

Furthermore, there may be a second time interval T₂ in which no current is supplied to the light emitting device 200 between the first time interval T₁ and the third time interval T₃. Furthermore, there may be a fourth time interval T₄ in which no current is supplied to the light emitting device 200 after the third time interval T₃. Through this, power consumption may be reduced. In this case, the second time interval T₂ may be shorter than the fourth time interval T₄. Furthermore, a sum of the first time interval T₁ and the second time interval T₂ may be equal to a sum of the third time interval T₃ and the fourth time interval T₄. Through this, a driving period may be maintained constant, but is not limited thereto.

Furthermore, the light emitting device 200 may be driven at 60 Hz or more to reduce flicker. In other words, the ninth current waveform may have a period that is repeated n times for 2n+2 times. When 2n+2 times is 60 seconds, it may be repeated a total of 30 or more times. In other words, the fourth-1 charge density per unit area C4-1 and the fourth-3 charge density per unit area C4-3 may be repeated 30 or more times each, and the light emitting device 200 may be turned on a total of 60 or more times.

In this case, the light emitting device 200 supplied with the ninth current waveform may emit a different dominant wavelength for each repeated time interval. For example, during a time interval in which the fourth-1 charge density per unit area C4-1 is supplied, a dominant wavelength of a longer wavelength may be emitted than during a time interval in which the fourth-3 charge density per unit area C4-3 is supplied. For example, during the time interval in which the fourth-1 charge density per unit area C4-1 is supplied, light having a dominant wavelength close to a green region may be emitted, and during the time interval in which the fourth-3 charge density per unit area C4-3 is supplied, light having a dominant wavelength close to a blue region may be emitted. Alternatively, during the time interval in which the fourth-1 charge density per unit area C4-1 is supplied, light having a dominant wavelength close to a red region may be emitted, and during the time interval in which the fourth-3 charge density per unit area C-3 is supplied, light having a dominant wavelength close to a green region may be emitted. Through this, when a certain time interval is repeated in the light emitting device 200 supplied with the ninth current waveform, the overlapped spectrum OS may have a spectrum having a white color temperature.

Meanwhile, the ninth current waveform is shown as a waveform including the first current density J₁ and the second current density J₂, but is not limited thereto. In addition, a plurality of light emitting apparatuses 1 may be driven with a plurality of different current densities. In this case, a charge density per unit area may be maintained constant during a current supply time. Through this, the same luminous intensity may be maintained even if a plurality of different current densities are supplied to a plurality of light emitting apparatuses 1.

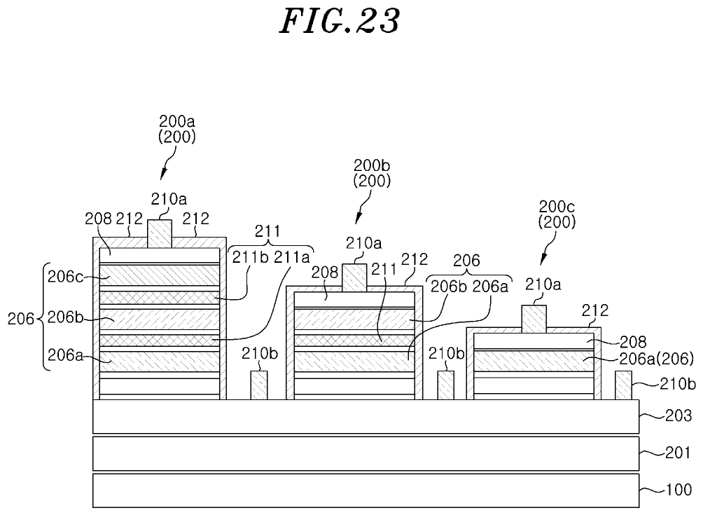

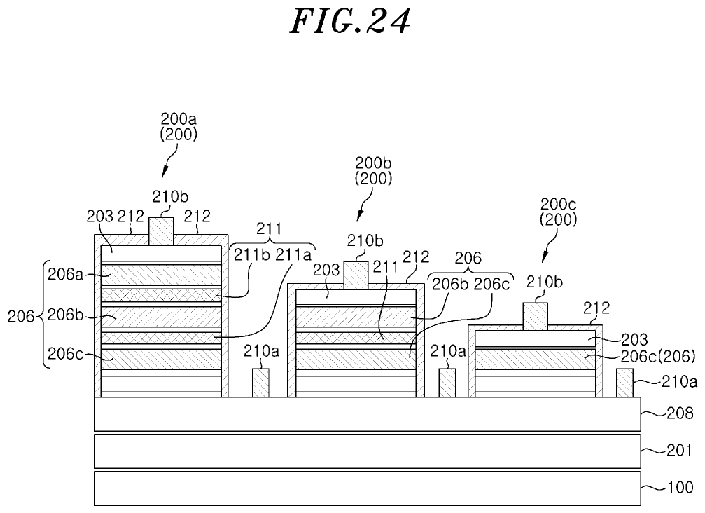

Hereinafter, a light emitting apparatus 1 according to a fifth embodiment will be described with reference to FIG. 23.

In describing the fifth embodiment, there are differences in that an intermediate layer 211 and an insulating film 212 are further included and a buffer layer 201 and a first conductivity-type semiconductor layer 203 of a plurality of light emitting devices 200 are integrally formed, and thus these differences will be mainly described.

The intermediate layer 211 is a layer that may control the movement of carriers distributed within the active region 206. The intermediate layer 211 may be composed of a P/N tunnel junction, P-GaN, N-GaN, etc.

The insulating film 212 may cover the active region 206, the intermediate layer 211, and the second conductivity-type semiconductor layer 208. The insulating film 212 may prevent charge leakage.

A first light emitting device 200a may include a plurality of intermediate layers 211 and a plurality of active regions 206. The plurality of active regions 206 included in the first light emitting device 200a may include a first active region 206a, a second active region 206b, and a third active region 206c. The plurality of intermediate layers 211 included in the first light emitting device 200a may include a first intermediate layer 211a and a second intermediate layer 211b.

The first intermediate layer 211a may be disposed between the first active region 206a and the second active region 206b. The second intermediate layer 211b may be disposed between the second active region 206b and the third active region 206c. The first active region 206a may be disposed between the first intermediate layer 211a and the first conductivity-type semiconductor layer 203. The third active region 206c may be disposed between the second intermediate layer 211b and the second conductivity-type semiconductor layer 208. The second active region 206b may be disposed between the first intermediate layer 211a and the second intermediate layer 211b. The first light emitting device 200a may generate light of different dominant wavelengths. In other words, the first light emitting device 200a may generate white light in which blue light, green light, and red light are mixed.

A second light emitting device 200b may include one intermediate layer 211 and a plurality of active regions 206. The plurality of active regions 206 included in the second light emitting device 200b may include a first active region 206a and a second active region 206b. The intermediate layer 211 may be disposed between the first active region 206a and the second active region 206b. The first active region 206a may be disposed between the first conductivity-type semiconductor layer 203 and the intermediate layer 211. The second active region 206b may be disposed between the intermediate layer 211 and the second conductivity-type semiconductor layer 208. The second light emitting device 200b may generate light of different dominant wavelengths. In other words, the second light emitting device 200b may generate light in which blue light and green light are mixed.

A third light emitting device 200c may include one active region 206. The active region 206 may be a first active region 206a. The third light emitting device 200c may generate blue light.

Hereinafter, a light emitting apparatus 1 according to a sixth embodiment will be described with reference to FIG. 24.

In describing the fifth embodiment, there is a difference in that a second conductivity-type semiconductor layer 208 of a plurality of light emitting devices 200 is stacked on a buffer layer 201 and integrally formed, and thus this difference will be mainly described.

A first light emitting device 200a may include a plurality of intermediate layers 211 and a plurality of active regions 206. The plurality of active regions 206 included in the first light emitting device 200a may include a first active region 206a, a second active region 206b, and a third active region 206c. The plurality of intermediate layers 211 included in the first light emitting device 200a may include a first intermediate layer 211a and a second intermediate layer 211b. The first intermediate layer 211a may be disposed between the third active region 206c and the second active region 206b. The second intermediate layer 211b may be disposed between the second active region 206b and the first active region 206a. The first active region 206a may be disposed between the second intermediate layer 211b and the first conductivity-type semiconductor layer 203. The third active region 206c may be disposed between the first intermediate layer 211a and the second conductivity-type semiconductor layer 208. The second active region 206b may be disposed between the first intermediate layer 211a and the second intermediate layer 211b. The first light emitting device 200a may generate light of different dominant wavelengths. In other words, the first light emitting device 200a may generate white light in which red light, green light, and blue light are mixed.

A second light emitting device 200b may include one intermediate layer 211 and a plurality of active regions 206. The plurality of active regions 206 included in the second light emitting device 200b may include a third active region 206c and a second active region 206b. The intermediate layer 211 may be disposed between the third active region 206c and the second active region 206b. The third active region 206c may be disposed between the second conductivity-type semiconductor layer 208 and the intermediate layer 211. The second active region 206b may be disposed between the intermediate layer 211 and the first conductivity-type semiconductor layer 203. The second light emitting device 200b may generate light of different dominant wavelengths. In other words, the second light emitting device 200b may generate light in which red light and green light are mixed.

A third light emitting device 200c may include one active region 206. The active region 206 may be a third active region 206c. The third light emitting device 200c may generate red light.

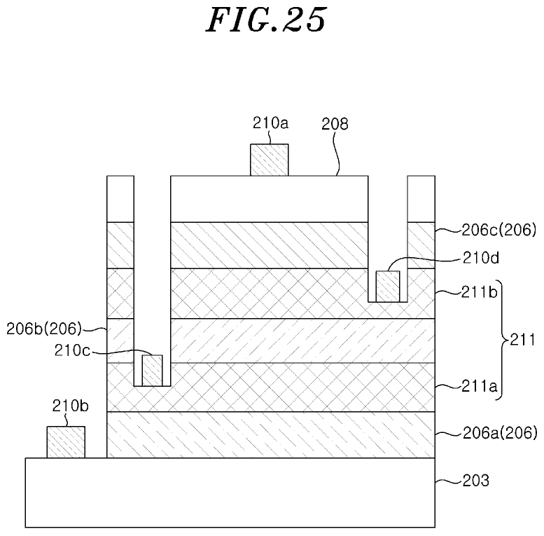

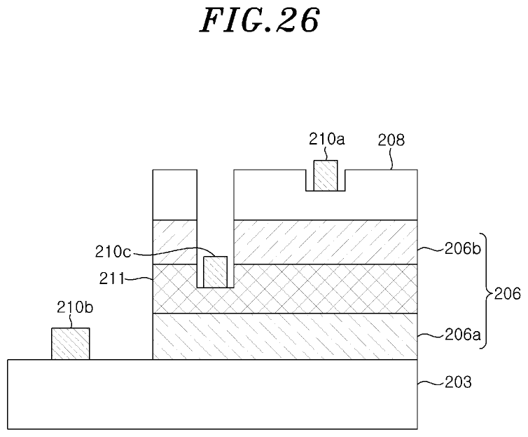

Hereinafter, a light emitting apparatus 1 according to a seventh embodiment will be described with reference to FIG. 25.

In describing the sixth embodiment, there is a difference in that a plurality of light emitting devices 200 further include a third electrode 210c and a fourth electrode 210d, and thus this difference will be mainly described.

A first light emitting device 200a may include a first electrode 210a, a second electrode 210b, a third electrode 210c, and a fourth electrode 210d.

The third electrode 210c may be electrically connected to a first intermediate layer 211a. The third electrode 210c may be electrically connected to a first active region 206a through the first intermediate layer 211a. Furthermore, the third electrode 210c may be electrically connected to a second conductivity-type semiconductor layer disposed on an upper region of the first active region 206a. A partial region of the first intermediate layer 211a may act as a second conductivity-type semiconductor layer of the first active region 206a. When a negative electrode and a positive electrode are respectively connected to the first electrode 210b and the third electrode 210c, electrons and holes may be recombined in the first active region 206a to emit photons, thereby emitting light.

Furthermore, the third electrode 210c may be electrically connected to a second active region 206b through the first intermediate layer 211a. The third electrode 210c may be electrically connected to a first conductivity-type semiconductor layer disposed on a lower region of the second active region 206b. A partial region of the first intermediate layer 211a may act as a first conductivity-type semiconductor layer for the second active region 206b. When a negative electrode and a positive electrode are respectively connected to the third electrode 210c and a fourth electrode 210d, electrons and holes may be recombined in the second active region 206b to emit photons, thereby emitting light. In addition, when a negative electrode and a positive electrode are respectively connected to the fourth electrode 210d and the second electrode 210b, electrons and holes may be recombined in the second active region 206b and the first active region 206a to emit photons, thereby emitting light. Through this, a spectrum in which a spectrum of the second active region 206b and a spectrum of the first active region 206a are mixed may be obtained. The first intermediate layer 211a or a second intermediate layer 211b may be a PN tunnel junction.

Furthermore, a third active region 206c may be electrically connected through the fourth electrode 210d. The fourth electrode 210d may be electrically connected to a first conductivity-type semiconductor layer disposed on a lower region of the third active region 206c. A partial region of the second intermediate layer 211b may act as a first conductivity-type semiconductor layer for the third active region 206c. When a positive electrode and a negative electrode are respectively connected to the fourth electrode 210d and the first electrode 210a, electrons and holes may be recombined in the third active region 206c to emit photons, thereby emitting light. In addition, when a positive electrode and a negative electrode are respectively connected to the first electrode 210a and the third electrode 210c, electrons and holes may be recombined in a third active layer (206c) and a second active layer (206b) to emit photons, thereby emitting light. Through this, a spectrum in which a spectrum of the second active region 206b and a spectrum of the third active region 206c are mixed may be obtained. Furthermore, when a positive electrode and a negative electrode are respectively connected to the first electrode 210a and the second electrode 210b, electrons and holes may be recombined in the third active region 206c, the second active region 206b, and a first active layer (206a) to emit photons, thereby emitting light. Through this, a spectrum in which a spectrum of the second active region 206b, a spectrum of the second active region 206b, and a spectrum of the first active region 206a are mixed may be obtained.

Through this electrode connection, the first light emitting device 200a may generate at least one of blue light, green light, or red light.

As a first example, the first light emitting device 200a may generate white light in which blue light, green light, and red light are mixed. As a second example, the first light emitting device 200a may generate light in which some of blue light, green light, and red light are mixed. As a third example, the first light emitting device 200a may generate any one of blue light, green light, or red light.

Hereinafter, a light emitting apparatus 1 according to an eighth embodiment will be described with reference to FIG. 26.

In describing the eighth embodiment, there is a difference in that a light emitting device 200 includes a third electrode 210c, and thus this difference will be mainly described.

A second light emitting device 200b may include a first electrode 210a, a second electrode 210b, and a third electrode 210c.

The third electrode 210c may be electrically connected to an intermediate layer 211. By the third electrode 210c, a first light emitting device 200a may generate at least one of blue light and green light.

As a first example, the second light emitting device 200b may generate light in which blue light and green light are mixed. As a second example, the second light emitting device 200b may generate either blue light or green light.

Hereinafter, with reference to FIG. 27, it will be described that when a current density supplied to a light emitting device 200 is controlled, a spectrum of light emitted from the light emitting device 200, particularly a dominant wavelength, is changed.

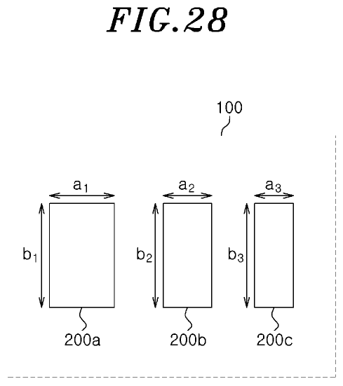

As the current density increases, a dominant wavelength of the light emitting device 200 may become shorter. For example, the controller 300 may be a driving device or a driving circuit that controls a magnitude of a current and a current supply time supplied to a plurality of light emitting devices 200 disposed on the substrate 100. The light emitting device 200 may change a dominant wavelength by changing a current density supplied by the controller 300. In addition, as shown in FIG. 28 described below, a dominant wavelength emitted from each light emitting device 200 may be varied by varying an area of the light emitting device 200.

Furthermore, as the dominant wavelength becomes longer, a wavelength change rate according to the current density may increase. For example, WD1 may be a graph of a change rate of a dominant wavelength for each current density of a light emitting device 200 having a shorter wavelength than WD2. WD1 may be a graph of a change rate of a dominant wavelength for each current density of a light emitting device 200 having a shorter wavelength than WD3. WD2 may be a graph of a change rate of a dominant wavelength for each current density of a light emitting device 200 having a wavelength in a region between WD1 and WD3.

In one example, when a dominant wavelength emitted from one of a plurality of light emitting devices 200 has a change rate of WD1 and a dominant wavelength emitted from another of the plurality of light emitting devices 200 has a change rate of WD2, the one of the plurality of light emitting devices 200 may have an active layer with a higher Al content than the other of the plurality of light emitting devices 200.

In another example, when a dominant wavelength emitted from one of a plurality of light emitting devices 200 has a change rate of WD1 and a dominant wavelength emitted from another of the plurality of light emitting devices 200 has a change rate of WD3, the other of the plurality of light emitting devices 200 may have an active layer with a higher In content than the one of the plurality of light emitting devices 200. Furthermore, an active layer of a light emitting device 200 that emits a dominant wavelength having a change rate of WD2 may have an intermediate value of an Al content value of an active layer included in a light emitting device 200 that emits a dominant wavelength having a change rate of WD1. Furthermore, an active layer of a light emitting device 200 that emits a dominant wavelength having a change rate of WD2 may have an intermediate value of an In content value of an active layer included in a light emitting device 200 that emits a dominant wavelength having a change rate of WD3.

For example, WD1 may be a graph showing a change rate of a dominant wavelength for each current density of a light emitting device 200 having a dominant wavelength in a blue wavelength region. WD2 may be a graph showing a change of a dominant wavelength for each current density of a light emitting device 200 having a dominant wavelength in a green wavelength region. WD3 may be a graph showing a change of a dominant wavelength for each current density of a light emitting device 200 having a dominant wavelength in a red wavelength region.

Hereinafter, a ninth embodiment will be described with reference to FIG. 28. In describing the ninth embodiment, there is a difference in that an area of at least some of a plurality of light emitting devices 200 may be formed differently so that a current value is changed, and thus this difference will be mainly described.

Even if the same current is supplied to a plurality of light emitting devices 200a, 200b, and 200c, if their areas are formed differently, the plurality of light emitting devices 200a, 200b, and 200c may have different current densities. Through this, the plurality of light emitting devices 200a, 200b, and 200c may emit different dominant wavelengths.

When a plurality of first light emitting devices 200a, second light emitting devices 200b, and third light emitting devices 200c are formed, and different current densities are supplied to the plurality of light emitting devices 200a, 200b, and 200c, a color reproduction rate of the overlapped spectrum OS may be increased.

The first light emitting device 200a may have a larger area than the second light emitting device 200b. Through this, the first light emitting device 200a may have a smaller current density than the second light emitting device 200b. A dominant wavelength of the first light emitting device 200a may be longer than a dominant wavelength of the second light emitting device 200b. For example, the first light emitting device 200a may have a dominant wavelength closer to a red wavelength region than the second light emitting device 200b.

A first minor axis a1 of the first light emitting device 200a may be larger than a second minor axis a2 of the second light emitting device 200b, and a first major axis b1 of the first light emitting device 200a may be the same as a second major axis b2 of the second light emitting device 200b, but is not limited thereto. In other words, the first major axis b1 of the first light emitting device 200a may be larger than the second major axis b2 of the second light emitting device 200b, and the first minor axis a1 of the first light emitting device 200a may have the same length as the second minor axis a2 of the second light emitting device 200b. Furthermore, the first major axis b1 and the first minor axis a1 of the first light emitting device 200a may be larger than the second major axis b2 and the second minor axis a2 of the second light emitting device 200b. Through this, an area of the first light emitting device 200a may be larger than an area of the second light emitting device 200b. A height of the first light emitting device 200a may be similar to a height of the second light emitting device 200b. A difference in height between the first light emitting device 200a and the second light emitting device 200b may be less than 10%.

The second light emitting device 200b may have a larger area than the third light emitting device 200c. Through this, the second light emitting device 200b may have a smaller current density than the third light emitting device 200c. Furthermore, a dominant wavelength of the second light emitting device 200b may be longer than a dominant wavelength of the third light emitting device 200c. For example, the second light emitting device 200b may have a dominant wavelength closer to a green wavelength region than the third light emitting device 200c. The third light emitting device 200c may have the smallest light-emitting area among the plurality of light emitting devices 200a, 200b, and 200c. Furthermore, the third light emitting device 200c may have the largest current density among the plurality of light emitting devices 200a, 200b, and 200c. The third light emitting device 200c may have a dominant wavelength close to a blue region.

A second minor axis a2 of the second light emitting device 200b may be larger than a third minor axis a3 of the third light emitting device 200c, and a second major axis b2 of the second light emitting device 200c and a third major axis b3 of the third light emitting device 200c may be the same, but is not limited thereto. In other words, a second major axis b2 of the second light emitting device 200b may be larger than a third major axis b3 of the third light emitting device 200c, and a second minor axis a2 of the second light emitting device 200b may have the same length as a third minor axis a3 of the third light emitting device 200c. Furthermore, the second major axis b2 and the second minor axis a2 of the second light emitting device 200b may be larger than the third major axis b3 and the third minor axis a3 of the third light emitting device 200c. Through this, an area of the second light emitting device 200c may be larger than an area of the third light emitting device 200c. A height of the second light emitting device 200c may be similar to a height of the third light emitting device 200c. A difference in height between the second light emitting device 200c and the third light emitting device 200c may be less than 10%.

Furthermore, to maintain a constant luminous flux in the plurality of light emitting devices 200a, 200b, and 200c having different areas, a time for which a current is applied to each light emitting device 200a, 200b, and 200c may be varied. Therefore, a charge density per unit area during a driving time of each light emitting device 200a, 200b, and 200c may be similar to each other. For example, the first light emitting device 200a may have a shorter driving time interval than the second light emitting device 200b. Furthermore, the second light emitting device 200b may have a shorter driving time interval than the third light emitting device 200c. Furthermore, the third light emitting device 200c may have the narrowest light-emitting area. Furthermore, the third light emitting device 200c may have the largest current density among the light emitting devices 200a, 200b, and 200c. The third light emitting device 200c may have a dominant wavelength close to a blue region.

Meanwhile, an operation of the plurality of light emitting devices 200 may be similar to an operation of the first to ninth embodiments, and through this, a color reproduction rate of the light emitting apparatus 1 may be increased.

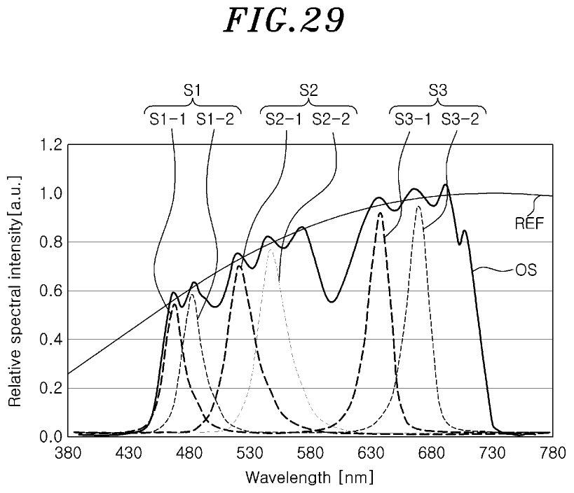

FIG. 29 is a diagram showing another embodiment of an overlapped spectrum OS in which a plurality of emission spectra S1, S2, and S3 are overlapped.

Referring to FIG. 29, an overlapped spectrum OS obtained by driving a plurality of light emitting devices 200 for a certain time may have a white spectrum similar to sunlight RF. A plurality of peaks and valleys may be formed in the overlapped spectrum OS.

To implement a white spectrum similar to sunlight RF, at least one of a first light emitting device 200a, a second light emitting device 200b, and a third light emitting device 200c may include at least one light-emitting part. Unlike FIG. 12, an overlapped intensity over time of a first-1 emission spectrum S1-1, a second-1 emission spectrum S2-1, and a third-1 emission spectrum S3-1 may be lower than an overlapped intensity of a first-2 emission spectrum S1-2, a second-2 emission spectrum S2-2, and a third-2 emission spectrum S3-2. For this, an application time of a current density applied to a plurality of light emitting devices 200 to emit the first-2 emission spectrum S1-2, the second-2 emission spectrum S2-2, and the third-2 emission spectrum S3-2 may be longer than an application time of a current density applied to emit the first-1 emission spectrum S1-1, the second-1 emission spectrum S2-1, and the third-1 emission spectrum S3-1.

Although the exemplary embodiments of the disclosed technology have been described as specific embodiments, these are merely examples, and the disclosed technology is not limited thereto, and should be interpreted as having the broadest scope according to the technical spirit disclosed in this specification. Those skilled in the art may implement patterns of unstated shapes by combining/substituting the disclosed embodiments, but these also do not depart from the scope of the disclosed technology. In addition, those skilled in the art may easily change or modify the disclosed embodiments based on this specification, and it is clear that such changes or modifications also belong to the scope of rights of the disclosed technology.

### DESCRIPTION OF THE REFERENCE NUMERALS

| | |
|---|---|
| 1: light emitting apparatus | 2: lighting apparatus |
| 3: display apparatus | 10: lighting body |
| 20: lighting cover | 30: display panel |
| 40: driving substrate | 50: optical sheet |
| 60: lower cover | 100: substrate |
| 200: light emitting device | 200a: first light emitting device |
| 200b: second light emitting device | 200c: third light emitting device |
| 201: buffer layer | 202: undoped layer |
| 203: first conductivity-type | 204: strain control layer |
| semiconductor layer | |
| 205: superlattice layer | 205a: first superlattice layer |
| 205b: second superlattice layer | 206: active region |
| 206a: first active region | 206b: second active region |
| 206c: third active region | 207: electron blocking layer |
| 208: second conductivity-type | 209: transparent electrode layer |
| semiconductor layer | |
| 210: electrode | 210a: first electrode |
| 210b: second electrode | 210c: third electrode |
| 210d; fourth electrode | 211: intermediate layer |
| 211a: first intermediate layer | 211b: second intermediate layer |
| 211c: third intermediate layer | 212: insulating film |
| 300: controller | |

What is claimed is:

1. A light emitting apparatus, comprising:
a substrate;
a first light emitting device disposed on the substrate and configured to generate light of a first emission spectrum having a first dominant wavelength by a current supplied through the substrate; and
a second light emitting device disposed on the substrate and configured to generate light of a second emission spectrum having a second dominant wavelength and at least partially overlapping with the first emission spectrum,
wherein an intensity of the first dominant wavelength and an intensity of the second dominant wavelength are different from each other.

2. The light emitting apparatus of claim 1, wherein the intensity of the first dominant wavelength changes in response to a current density supplied to the first light emitting device, and
the intensity of the second dominant wavelength changes in response to a current density supplied to the second light emitting device.

3. The light emitting apparatus of claim 2, wherein when the current density supplied to the first light emitting device increases, a wavelength of the first dominant wavelength decreases, and the intensity of the first dominant wavelength increases, and when the current density supplied to the first light emitting device decreases, the wavelength of the first dominant wavelength increases, and the intensity of the first dominant wavelength decreases, and
when the current density supplied to the second light emitting device increases, a wavelength of the second dominant wavelength decreases, and the intensity of the second dominant wavelength increases, and when the current density supplied to the second light emitting device decreases, the wavelength of the second dominant wavelength increases, and the intensity of the second dominant wavelength decreases.

4. The light emitting apparatus of claim 1, further comprising:
a controller configured to control a current density supplied to the first light emitting device and a current density supplied to the second light emitting device to control the first dominant wavelength and the second dominant wavelength.

5. The light emitting apparatus of claim 4, wherein the controller is further configured to control the current density supplied to the first light emitting device to be smaller than the current density supplied to the second light emitting device.

6. The light emitting apparatus of claim 5, wherein the controller is further configured to control the current such that the current is supplied to the first light emitting device and the second light emitting device for a predetermined current supply time, and
a first current supply time during which the current is supplied to the first light emitting device is greater than a second current supply time during which the current is supplied to the second light emitting device.

7. The light emitting apparatus of claim 6, wherein the first current supply time during which current is supplied to the first light emitting device is shorter than the second current supply time during which current is supplied to the second light emitting device.

8. The light emitting apparatus of claim 7, wherein the controller is further configured to control the current such that a period in which no current is supplied to the first light emitting device and the second light emitting device is formed between the first current supply time during which the current is supplied to the first light emitting device and the second current supply time during which the current is supplied to the second light emitting device.

9. The light emitting apparatus of claim 8, wherein a time of the period in which no current is supplied is shorter than the first current supply time during which the current is supplied to the first light emitting device.

10. The light emitting apparatus of claim 8, wherein a time of the period in which no current is supplied is longer than the first current supply time during which the current is supplied to the first light emitting device.

11. The light emitting apparatus of claim 4, further comprising:
a third light emitting device disposed on the substrate and configured to generate light of a third emission spectrum having a third dominant wavelength and at least partially overlapping with the second emission spectrum by the current supplied through the substrate,
wherein the controller is further configured to control a current density supplied to the third light emitting device to control the third dominant wavelength, and control the current density supplied to the third light emitting device to be greater than the current density supplied to the second light emitting device.

12. The light emitting apparatus of claim 1, wherein the first light emitting device and the second light emitting device generate light such that an overlapped spectrum is formed in which the first emission spectrum and the second emission spectrum at least partially overlap each other, and
a plurality of peaks are formed in the overlapped spectrum.

13. The light emitting apparatus of claim 12, wherein the overlapped spectrum has a color temperature corresponding to white light.

14. The light emitting apparatus of claim 1, wherein each of the first light emitting device and the second light emitting device comprises:
a first conductivity-type semiconductor layer;
an active region stacked on the first conductivity-type semiconductor layer; and
a second conductivity-type semiconductor layer stacked on the active region.

15. The light emitting apparatus of claim 1, wherein each of the first light emitting device and the second light emitting device comprises:
a first conductivity-type semiconductor layer;
a superlattice layer stacked above the first conductivity-type semiconductor layer; and
a second conductivity-type semiconductor layer stacked above the superlattice layer,
wherein the superlattice layer includes Indium Gallium Nitride (InGaN).

16. The light emitting apparatus of claim 15, wherein a plurality of the superlattice layers are formed, and
wherein the plurality of superlattice layers comprise:
a first superlattice layer stacked on the first conductivity-type semiconductor layer; and
a second superlattice layer stacked above the first superlattice layer, and
a content of indium included in the first superlattice layer and a content of indium included in the second superlattice layer are different from each other.

17. A light emitting apparatus, comprising:
a substrate;
a first light emitting device disposed on the substrate and configured to generate light of a first emission spectrum having a first dominant wavelength; and
a second light emitting device disposed on the substrate and configured to generate light of a second emission spectrum having a second dominant wavelength and at least partially overlapping with the first emission spectrum,
wherein each of the first light emitting device and the second light emitting device comprises:
a first conductivity-type semiconductor layer;
an active region stacked above the first conductivity-type semiconductor layer;
a second conductivity-type semiconductor layer stacked above the active region;
a first electrode electrically connected to the second conductivity-type semiconductor layer; and
a second electrode electrically connected to the first conductivity-type semiconductor layer, and
the second electrode of the first light emitting device and the second electrode of the second light emitting device are electrically connected to the second conductivity-type semiconductor layer of the first light emitting device and the second light emitting device.

18. A light emitting apparatus, comprising:
a substrate;
a first active region disposed on the substrate and configured to generate light of a first emission spectrum having a first dominant wavelength by a current supplied through the substrate; and
a second active region disposed on the substrate and configured to generate light of a second emission spectrum having a second dominant wavelength and at least partially overlapping with the first emission spectrum,
wherein an intensity at the first dominant wavelength and an intensity at the second dominant wavelength are different from each other.

19. The light emitting apparatus of claim 18, wherein the intensity at the first dominant wavelength changes in response to a current density supplied to the first active region, and
the intensity at the second dominant wavelength changes in response to a current density supplied to the second active region.

20. The light emitting apparatus of claim 18, further comprising:
a controller configured to control the current density supplied to the first active region and a current density supplied to the second active region to control the first dominant wavelength and the second dominant wavelength.
